(19) United States
(12) Patent Application Publication
(10) Pub. No.: US 2025/0374796 A1
(43) Pub. Date: Dec. 4, 2025

(54) DISPLAY DEVICE, WEARABLE DEVICE, AND ELECTRONIC DEVICE INCLUDING DISPLAY DEVICE

(71) Applicant: Samsung Display Co., LTD., Yongin-si (KR)

(72) Inventors: Hyeon Jeong IM, Yongin-si (KR); Hyo Min KO, Yongin-si (KR); Dae Woong LEE, Yongin-si (KR)

(21) Appl. No.: 19/065,885

(22) Filed: Feb. 27, 2025

(30) Foreign Application Priority Data
Jun. 4, 2024 (KR) 10-2024-0073170

(51) Int. Cl. H10K 59/80; H10K 59/35; H10K 102/00

(52) U.S. Cl. CPC H10K 59/80518; H10K 59/353; H10K 59/80521; H10K 59/876; H10K 2102/351

(57) ABSTRACT

A display device includes: a first light emitting element on a first reflective electrode; a second light emitting element on a second reflective electrode; and a third light emitting element on a third reflective electrode. The first light emitting element, the second light emitting element, and the third light emitting element share a light emitting structure and a cathode electrode. The light emitting structure includes a first light emitting portion, a second light emitting portion, and a third light emitting portion sequentially stacked. A thickness of the third light emitting portion is greater than a sum of a thickness of the first light emitting portion and a thickness of the second light emitting portion.

### CROSS-REFERENCE TO RELATED APPLICATION

The present application claims priority to and the benefit of Korean Patent Application No. 10-2024-0073170, filed on Jun. 4, 2024, in the Korean Intellectual Property Office, the entire disclosure of which is incorporated by reference herein.

### BACKGROUND

### 1. Field

Aspects of embodiments of the present disclosure relate to a display device, a wearable device, and an electronic device including the display device.

### 2. Description of the Related Art

As information technology develops, the importance of display devices, which are a connection medium between users and information, is emerging.

Accordingly, the use of display devices, such as a liquid crystal display device, an organic light emitting display device, and the like, has been increasing.

The display device displays an image using pixels. In order to implement augmented reality (AR), virtual reality (VR), and mixed reality (MR), the display device may include more pixels disposed on a smaller display surface.

As the gap between the pixels narrows, a leakage current through a common layer of adjacent pixels may cause issues.

The above information disclosed in this Background section is for enhancement of understanding of the background of the present disclosure, and therefore, it may contain information that does not constitute prior art.

### SUMMARY

Embodiments of the present disclosure may be directed to a display device and a wearable device that may prevent or substantially prevent a leakage current through a common layer between adjacent pixels.

According to one or more embodiments of the present disclosure, a display device includes: a first light emitting element including a first reflective electrode; a second light emitting element including a second reflective electrode; and a third light emitting element including a third reflective electrode. The first light emitting element, the second light emitting element, and the third light emitting element share a light emitting structure and a cathode electrode. The light emitting structure includes a first light emitting portion, a second light emitting portion, and a third light emitting portion sequentially stacked. A thickness of the third light emitting portion is greater than a sum of a thickness of the first light emitting portion and a thickness of the second light emitting portion.

In an embodiment, the thickness of the third light emitting portion may be 2.5 times or more than the sum of the thickness of the first light emitting portion and the thickness of the second light emitting portion.

In an embodiment, a thickness of a hole transport portion included in the third light emitting portion may be greater than the sum of the thickness of the first light emitting portion and the thickness of the second light emitting portion.

In an embodiment, the display device may further include a separator between the first light emitting element, the second light emitting element, and the third light emitting element. The light emitting structure may further include: a first charge generation layer between the first light emitting portion and the second light emitting portion; and a second charge generation layer between the second light emitting portion and the third light emitting portion. Each of the first light emitting portion, the first charge generation layer, the second light emitting portion, and the second charge generation layer may be disconnected by the separator, and the cathode electrode may extend on an upper portion of the separator without being disconnected.

In an embodiment, a distance between a first transparent electrode and a first reflective electrode of the first light emitting element may be smaller than a distance between a second transparent electrode and a second reflective electrode of the second light emitting element.

In an embodiment, the distance between the second transparent electrode and the second reflective electrode of the second light emitting element may be smaller than a distance between a third transparent electrode and a third reflective electrode of the third light emitting element.

In an embodiment, the first light emitting portion may include a first light emitting layer configured to emit light of a first color; the second light emitting portion may include a second light emitting layer configured to emit light of a second color; the third light emitting portion may include a third light emitting layer configured to emit light of a third color; and the first color, the second color, and the third color may be different colors from each other.

In an embodiment, the first color may be green, the second color may be blue, and the third color may be red.

In an embodiment, the first light emitting layer may be located in a first resonance layer from among five resonance layers for the first color; the second light emitting layer may be located in a second resonance layer from among six resonance layers for the second color; and the third light emitting layer may be located in a fourth resonance layer from among four resonance layers for the third color.

In an embodiment, the first light emitting layer may be spaced from the third reflective electrode at an interval of 550 Å or more and 750 Å or less; the second light emitting layer may be spaced from the second reflective electrode at an interval of 1400 Å or more and 1600 Å or less; and the third light emitting layer may be spaced from the first reflective electrode at an interval of 5600 Å or more and 5800 Å or less.

In an embodiment, the second transparent electrode and the second reflective electrode of the second light emitting element may be spaced from each other at an interval of 150 Å or more and 350 Å or less; and the third transparent electrode and the third reflective electrode of the third light emitting element may be spaced apart from each other at an interval of 400 Å or more and 600 Å or less.

In an embodiment, the first color may be red, the second color may be blue, and the third color may be green.

In an embodiment, the first light emitting layer may be located in a first resonance layer from among four resonance layers for the first color; the second light emitting layer may be located in a second resonance layer from among six resonance layers for the second color; and the third light emitting layer may be located in a fifth resonance layer from among five resonance layers for the third color.

In an embodiment, the first light emitting layer may be spaced from the first reflective electrode at an interval of 500 Å or more and 700 Å or less; the second light emitting layer may be spaced from the second reflective electrode at an interval of 1400 Å or more and 1600 Å or less; and the third light emitting layer may be spaced from the third reflective electrode at an interval of 6400 Å or more and 6600 Å or less.

In an embodiment, the second transparent electrode and the second reflective electrode of the second light emitting element may be spaced from each other at an interval of 200 Å or more and 400 Å or less; and the third transparent electrode and the third reflective electrode of the third light emitting element may be spaced from each other at an interval of 600 Å or more and 800 Å or less.

In an embodiment, the display device may further include a substrate, and a distance between the substrate and the first reflective electrode, a distance between the substrate and the second reflective electrode, and a distance between the substrate and the third reflective electrode may be the same as each other.

In an embodiment, a distance between the cathode electrode of the first light emitting element and the substrate, a distance between the cathode electrode of the second light emitting element and the substrate, and a distance between the cathode electrode of the third light emitting element and the substrate may be different from each other.

In an embodiment, the display device may further include a substrate, and a distance between the substrate and the first reflective electrode, a distance between the substrate and the second reflective electrode, and a distance between the substrate and the third reflective electrode may be different from each other.

In an embodiment, a distance between the cathode electrode of the first light emitting element and the substrate, a distance between the cathode electrode of the second light emitting element and the substrate, and a distance between the cathode electrode of the third light emitting element and the substrate may be the same as each other.

According to one or more embodiments of the present disclosure, a wearable device includes: a first display panel; and a second display panel, each of the first display panel and the second display panel including: a first light emitting element including a first reflective electrode; a second light emitting element including a second reflective electrode; and a third light emitting element including a third reflective electrode. The first light emitting element, the second light emitting element, and the third light emitting element share a light emitting structure and a cathode electrode.

The light emitting structure includes a first light emitting portion, a second light emitting portion, and a third light emitting portion sequentially stacked. A thickness of the third light emitting portion is greater than a sum of a thickness of the first light emitting portion and a thickness of the second light emitting portion.

An electronic device includes a processor to provide input image data; and a display device to display an image based on the input image data, the display device including: a first light emitting element including a first reflective electrode; a second light emitting element including a second reflective electrode; and a third light emitting element including a third reflective electrode, wherein the first light emitting element, 1 the second light emitting element, and the third light emitting element share a light emitting structure and a cathode electrode, wherein the light emitting structure includes a first light emitting portion, a second light emitting portion, and a third light emitting portion sequentially stacked, and wherein a thickness of the third light emitting portion is greater than a sum of a thickness of the first light emitting portion and a thickness of the second light emitting portion.

According to some embodiments of the present disclosure, it may be possible to prevent or substantially prevent a leakage current through a common layer between adjacent pixels of a display device, a wearable device, and an electronic device including the display device.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 illustrates a block diagram of a display device according to an embodiment.

FIG. 2 illustrates a block diagram of a sub-pixel.

FIG. 3 is a schematic circuit diagram of a sub-pixel according to an embodiment.

FIG. 4 illustrates a top plan view of a display panel of FIG. 1 according to an embodiment.

FIG. 5 illustrates an exploded perspective view of a portion of the display panel of FIG. 4.

FIG. 6 illustrates a top plan view of one pixel of FIG. 5 according to an embodiment.

FIG. 7 illustrates a cross-sectional view taken along the line I-l′ of FIG. 6.

FIG. 8A and FIG. 8B illustrate cross-sectional views taken along the line I-I′ of FIG. 6 according to one or more embodiments.

FIG. 9 illustrates a cross-sectional view of a light emitting structure included in one light emitting element according to an embodiment.

FIG. 10 illustrates a cross-sectional view of a light emitting structure included in one light emitting element according to an embodiment.

FIG. 11A illustrates first to third light emitting elements according to an embodiment of the present disclosure.

FIG. 11B illustrates first to third light emitting elements according to an embodiment of the present disclosure.

FIG. 12 illustrates first to third light emitting elements according to an embodiment of the present disclosure.

FIG. 13A illustrates first to third light emitting elements according to an embodiment of the present disclosure.

FIG. 13B illustrates first to third light emitting elements according to an embodiment of the present disclosure.

FIG. 14 illustrates first to third light emitting elements according to an embodiment of the present disclosure.

FIG. 15 is a table illustrating a light emitting efficiency of first to third light emitting elements according to some embodiments of the present disclosure.

FIG. 16 illustrates a top plan view of one pixel of FIG. 5 according to an embodiment.

FIG. 17 illustrates a top plan view of one pixel of FIG. 5 according to an embodiment.

FIG. 18 illustrates a block diagram of a display system according to an embodiment.

FIG. 19 illustrates a perspective view of an example of an application of the display system of FIG. 18.

FIG. 20 illustrates a head-mounted display device of FIG. 19 worn on a user.

FIG. 21 is a schematic block diagram illustrating an electronic device including a display device in accordance with an embodiment.

FIG. 22 is a schematic diagram illustrating an example where the electronic device of FIG. 21 is a smartphone.

FIG. 23 is a schematic diagram illustrating an example where the electronic device of FIG. 21 is a tablet computer.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Further, the term the “same” and the like may include the expression “substantially the same.” Other terms may also include expressions in which the term “substantially” is omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as 1 having a meaning that is consistent with their meaning in the context of the relevant art and/or the present specification, and should not be interpreted in an idealized or overly formal sense, unless expressly so defined herein.

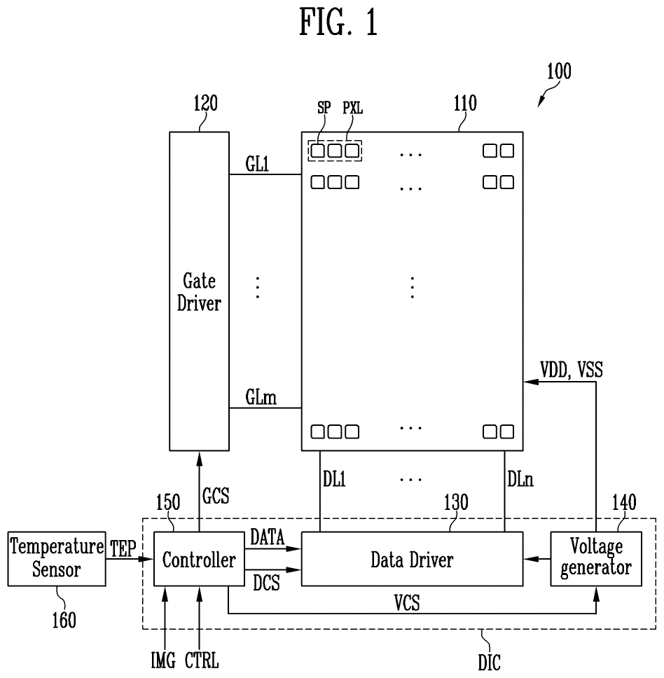

FIG. 1 illustrates a block diagram of a display device according to an embodiment.

Referring to FIG. 1, the display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm, where m is a natural number. The sub-pixels SP may be connected to the data driver 130 through first to n-th data lines DL1 to DLn, where n is a natural number.

Each of the sub-pixels SP may include at least one light emitting element to generate light. Accordingly, the sub-pixels SP may generate light of a desired color (e.g., a specific or predetermined color), such as red, green, blue, cyan, magenta, yellow, or the like. Two or more of the sub-pixels SP may configure one pixel PXL. For example, as shown in FIG. 1, three sub-pixels may configure one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In some embodiments, the gate control signal GCS may include a start signal indicating the start of each frame, a horizontal synchronization signal for outputting gate signals in synchronization with a timing at which data signals are applied, and the like.

The gate driver 120 may be disposed on one side of the display panel 110. However, the present disclosure is not limited thereto. For example, the gate driver 120 may be divided into two or more physically and/or logically separated drivers, and the drivers may be disposed on one side of the display panel 110 and another side (e.g., an opposite side) of the display panel 110 opposite to the one side. As described 1 above, the gate driver 120 may be disposed around the display panel 110 in various suitable forms according to embodiments.

The data driver 130 is connected to the sub-pixels SP arranged in a column direction through the first to n-th data lines DL1 to DLn. The data driver 130 receives image data (DATA) and a data control signal DCS from the controller 150. The data driver 130 operates in response to the data control signal DCS. In some embodiments, the data control signal DCS may include a source start pulse, a source shift clock, a source output enable signal, and the like.

The data driver 130 may use voltages from the voltage generator 140 to apply data signals having grayscale voltages (e.g., grayscale levels or values) corresponding to the image data DATA to the first to n-th data lines DL1 to DLn. When a gate signal is applied to each of the first to m-th gate lines GL1 to GLn, data signals corresponding to the image data DATA may be applied to the data lines DL1 to DLm. Accordingly, the selected sub-pixels SP may generate light corresponding to the data signals. Accordingly, an image is displayed on the display panel 110.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate a plurality of voltages, and may provide the generated voltages to the constituent elements of the display device 100. For example, the voltage generator 140 may generate a plurality of voltages by receiving an input voltage from the outside of the display device 100, adjusting the received voltage, and regulating the adjusted voltage.

The voltage generator 140 may generate a first power voltage VDD and a second power voltage VSS, and may provide the generated first and second power voltages VDD and VSS to the sub-pixels SP. The first power voltage VDD may have a relatively higher voltage level, and the second power voltage VSS may have a voltage level lower than that of the first power voltage VDD. In other embodiments, the first 1 power voltage VDD or the second power voltage VSS may be provided by an external device of the display device 100.

In addition, the voltage generator 140 may generate various suitable voltages. For example, the voltage generator 140 may generate an initialization voltage applied to the sub-pixels SP. For example, during a sensing operation to sense electrical characteristics of transistors and/or light emitting elements of the sub-pixels SP, a reference voltage (e.g., a predetermined reference voltage) may be applied to the first to n-th data lines DL1 to DLn, and the voltage generator 140 may generate the reference voltage.

The controller 150 controls various operations of the display device 100. The controller 150 receives input image data IMG and a control signal CTRL for controlling the display of the input image data IMG, from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. In some embodiments, the controller 150 may output the image data DATA by aligning the input image data IMG to be suitable for a disposition of the sub-pixels SP.

Two or more components from among the data driver 130, the voltage generator 140, and/or the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components from each other within one driver integrated circuit DIC. In other embodiments, at least one of the data driver 130, the voltage generator 140, or the controller 150 may be provided as a component separated from the driver integrated circuit DIC.

In some embodiments, the display device 100 may include at least one temperature sensor 160. The temperature sensor 160 may sense a surrounding temperature, and may generate temperature data TEP representing the sensed temperature. In some embodiments, the temperature sensor 160 may be disposed to be adjacent to the display panel 110 and/or the driver integrated circuit DIC.

The controller 150 may control various operations of the display device 100 in response to the temperature data TEP. In some embodiments, the controller 150 may adjust the luminance of an image output from the display panel 110 in response to the temperature data TEP. For example, the controller 150 may control the data signals and the first and second power voltages VDD and VSS by controlling the components, such as the data driver 130 and/or the voltage generator 140.

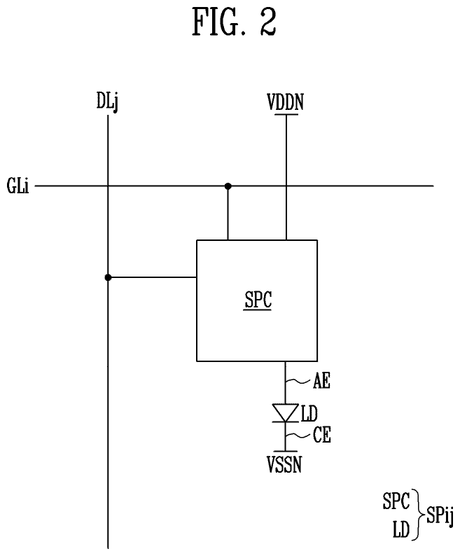

FIG. 2 illustrates a block diagram of a sub-pixel.

Referring to FIG. 2, from among the sub-pixels SP described above with reference to FIG. 1, a sub-pixel SPij disposed in an i-th row (where i is an integer greater than or equal to 1 and less than or equal to m) and a j-th column (where j is an integer greater than or equal to 1 and less than or equal to n) is illustrated as a representative example. The sub-pixel SPij may include a sub-pixel circuit SPC and a light emitting element LD.

The light emitting element LD is connected between the first power voltage node VDDN and a second power voltage node VSSN. In this case, the first power voltage node VDDN may be a node that transmits the first power voltage VDD of FIG. 1, and the second power voltage node VSSN may be a node that transmits the second power voltage VSS.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi of the first to m-th gate lines GL1 to GLm described above with reference to FIG. 1, and a j-th data line DLj of the first to n-th data lines DL1 to DLn. The sub-pixel circuit SPC may control the light emitting element LD according to signals received through the signal lines.

The sub-pixel circuit SPC may operate in response to a gate signal received through the i-th gate line GLi. The sub-pixel circuit SPC may receive a data signal through the j-th data line DLj. For example, the sub-pixel circuit SPC may respond to the gate signal to store a voltage corresponding to the data signal. Based on the voltage stored in the sub-pixel circuit SPC, the light emitting element LD may generate light having a luminance corresponding to the data signal.

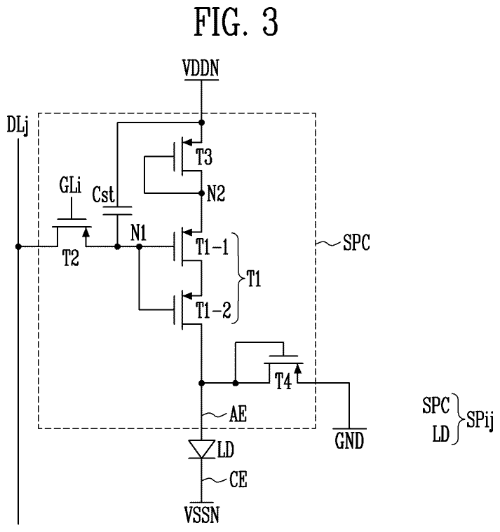

FIG. 3 is a schematic circuit diagram of a sub-pixel according to an embodiment.

Referring to FIG. 3, the sub-pixel SPij may include the sub-pixel circuit SPC and the light emitting element LD. The sub-pixel circuit SPC may include first to fourth transistors T1 to T4 and a storage capacitor Cst.

In the first transistor T1, a gate electrode may be connected to a first node N1, a first electrode may be connected to a second node N2, and a second electrode may be connected to the anode electrode AE of the light emitting element LD. The first transistor T1 may include sub-transistors T1-1 and T1-2 connected in series with each other. The first transistor T1 may be a driving transistor.

In the second transistor T2, a gate electrode may be connected to the i-th gate line GLi, a first electrode may be connected to the j-th data line DLj, and a second electrode may be connected to the first node N1.

In the third transistor T3, a gate electrode may be connected to the second node N2, a first electrode may be connected to the first power voltage node VDDN, and a second electrode may be connected to the second node N2.

In the fourth transistor T4, a gate electrode and a first electrode may be connected to the anode electrode AE of the light emitting element LD, and a second electrode may receive a reference voltage GND. The reference voltage GND may be smaller than the first power voltage VDD. In an embodiment, the reference voltage GND may be the same or substantially the same as the second power voltage VSS. In another embodiment, the reference voltage GND may be different from the second power voltage VSS.

In the storage capacitor Cst, a first electrode may be connected to the first power voltage node VDDN, and a second electrode may be connected to the first node N1.

The light emitting element LD may include the anode electrode AE, the cathode electrode CE, and a light emitting structure. The light emitting structure may be disposed between the anode electrode AE and the cathode electrode CE.

When a gate signal having a turn-on level (e.g., a low level) is applied to the i-th gate line GLi, the second transistor T2 may be turned on. In this case, the data signal applied to the j-th data line DLj may be applied to the first node N1 through the second transistor T2. The storage capacitor Cst may maintain or substantially maintain the voltage of the data signal. In response to the voltage of the data signal, the first transistor T1 may determine an amount of a driving current flowing from the first power voltage node VDDN to the second power voltage node VSSN. The light emitting element LD may emit light having a luminance corresponding to the amount of the driving current.

The third transistor T3 and the fourth transistor T4 may be diode-connected transistors, which may limit the direction of the current so that the current does not flow in a reverse direction. In some embodiments, the third transistor T3 and the fourth transistor T4 may be omitted from the sub-pixel circuit SPC. When the third transistor T3 is omitted, the second node N2 may be directly connected to the first power voltage node VDDN.

The first to fourth transistors T1 to T4 may be P-type transistors. Each of the transistors T1 to T4 may be a metal oxide silicon field effect transistor (MOSFET). However, the present disclosure is not limited thereto. For example, at least one of the transistors T1 to T4 may be an N-type transistor.

In some embodiments, the transistors T1 to T6 may include an amorphous silicon semiconductor, a monocrystalline silicon semiconductor, a polycrystalline silicon semiconductor, and/or an oxide semiconductor.

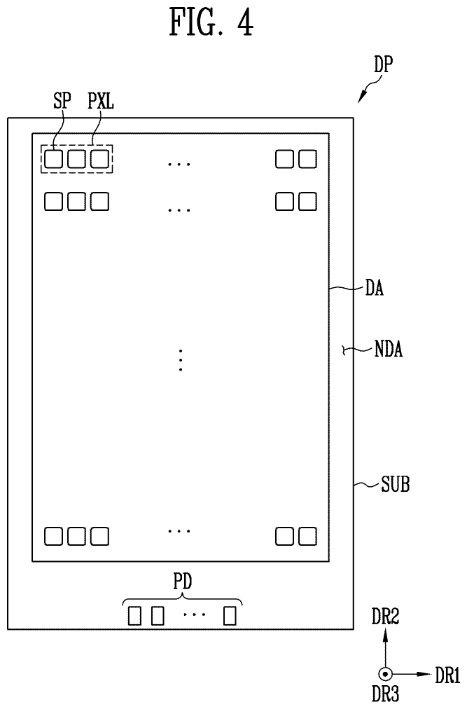

FIG. 4 illustrates a top plan view of a display panel of FIG. 1 according to an embodiment.

Referring to FIG. 4, the display panel DP may be the same or substantially the same as the display panel 110 described above with reference to FIG. 1. The display panel DP may include a display area DA and a non-display area NDA. The display panel DP displays an image through the display area DA. The non-display area NDA may be disposed around the display area DA.

The display panel DP may include a substrate SUB, sub-pixels SP, and pads PD.

When the display panel DP is used as a display screen for a head mounted display (HMD), a virtual reality (VR) device, a mixed reality (MR) device, or an augmented reality (AR) device, the display panel DP may be positioned to be very close to the user's eyes. In this case, the sub-pixels SP having a relatively high integration may be desired. In order to increase the integration of the sub-pixels SP, the substrate SUB may be provided as a silicon substrate. The sub-pixels SP and/or the display panel DP may be formed on the substrate SUB, which may be a silicon substrate. The display device 100 (e.g., see FIG. 1) including the display panel DP formed on the substrate SUB, which may be a silicon substrate, may be referred to as an OLED on silicon (OLEDoS) display device.

The sub-pixels SP are disposed in the display area DA on the substrate SUB. The sub-pixels SP may be arranged in a matrix format along a first direction DR1 and a second direction DR2 that crosses or intersects the first direction DR1. However, the present disclosure is not limited thereto. For example, the sub-pixels SP may be arranged in a zigzag form along first direction DR1 and second direction DR2. For example, the sub-pixels SP may be disposed in a diamond shape form (e.g., a PENTILE® shape, PENTILE® being a duly registered trademark of Samsung Display Co., Ltd.). The first direction DR1 may be a row direction, and the second direction DR2 may be a column direction.

Two or more of the plurality of sub-pixels SP may configure one pixel PXL.

A constituent element to control the sub-pixels SP may be disposed in the non-display area NDA on the substrate SUB. For example, wires connected to the sub-pixels SP, such as the first to m-th gate lines GL1 to GLm and the first to n-th data lines DL1 to DLn described above with reference to FIG. 1, may be disposed in the non-display area NDA.

At least one of the gate driver 120, the data driver 130, the voltage generator 140, the controller 150, or the temperature sensor 160 described above with reference to FIG. 1 may be integrated in the non-display area NDA of the display panel DP. In some embodiments, the gate driver 120 may be mounted on the display panel DP, and may be disposed in the non-display area NDA. In other embodiments, the gate driver 120 may be implemented as an integrated circuit separated from the display panel DP. In some embodiments, the temperature sensor 160 may be disposed in the non-display area NDA to detect the temperature of the display panel DP.

The pads PD are disposed in the non-display area NDA on the substrate SUB. The pads PD may be electrically connected to the sub-pixels SP through the wires. For example, the pads PD may be connected to the sub-pixels SP through the first to n-th data lines DL1 to DLn.

The pads PD may interface the display panel DP to other constituent elements of the display device 100 (e.g., see FIG. 1). In some embodiments, voltages and signals used for the operations of the constituent elements included in the display panel DP may be provided from the driver integrated circuit DIC described above with reference to FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In some embodiments, the circuit board may be electrically connected to the pads PD by using a conductive adhesive member, such as an anisotropic conductive film. In this case, the circuit board may be a flexible printed circuit board (FPCB) or a flexible film including (e.g., made of) a flexible material. The driver integrated circuit DIC may be mounted on the circuit board to be electrically connected to the pads PD. In some embodiments, the display area DA may have various suitable

shapes. The display area DA may have a closed-loop shape including sides of a straight line and/or a curved line. For example, the display area DA may have various suitable shapes, such as a polygonal shape, a circular shape, a semicircular shape, and an elliptical shape.

In some embodiments, the display panel DP may have a flat or substantially flat display surface. In other embodiments, the display panel DP may have a display surface that is at least partially rounded. In some embodiments, the display panel DP may be bendable, foldable, or rollable. In this case, the display panel DP and/or the substrate SUB may include various suitable materials having flexible properties.

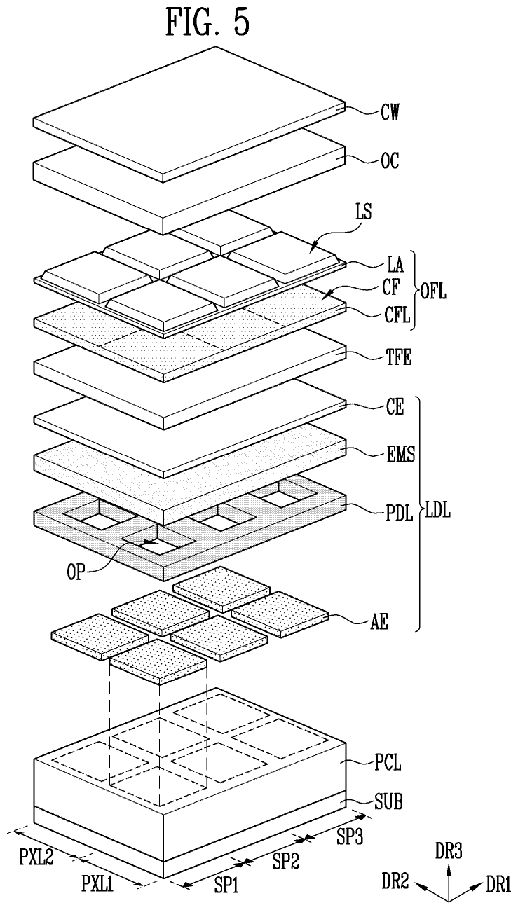

FIG. 5 illustrates an exploded perspective view of a portion of the display panel of FIG. 4. In FIG. 5, for convenience of illustration, a portion of the display panel DP corresponding to two pixels PXL1 and PXL2 from among the pixels PXL described above with reference to FIG. 4 is schematically shown. Portions of the display panel DP corresponding to the other remaining pixels may be configured the same or substantially the same (or similarly).

Referring to FIG. 4 and FIG. 5, each of the first and second pixels PXL1 and PXL2 may include first to third sub-pixels SP1, SP2, and SP3. However, the present disclosure is not limited thereto. For example, each of the first and second pixels PXL1 and PXL2 may include four sub-pixels, or two sub-pixels.

In FIG. 5, the first to third sub-pixels SP1, SP2, and SP3 are illustrated as having quadrangular shapes, and as having the same sizes as each other when viewed in the third direction DR3 crossing the first and second directions DR1 and DR2. However, the present disclosure is not limited thereto. The first to third sub-pixels SP1, SP2, and SP3 may be variously modified to have various suitable shapes.

The display panel DP may include a substrate SUB, a pixel circuit layer PCL, a light emitting element layer LDL, an encapsulation layer TFE, an optical functional layer OFL, an overcoat layer OC, and a cover window CW.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, an epitaxial layer, a silicon on Insulator (SOI) layer, or a semiconductor on insulator (SeOl) layer. In other embodiments, the substrate SUB may include a glass substrate. In other embodiments, the substrate SUB may include a polyimide (PI) substrate.

The pixel circuit layer PCL is disposed on the substrate SUB. The substrate SUB and/or the pixel circuit layer PCL may include insulating layers, and conductive patterns disposed between the insulating layers. The conductive patterns of the pixel circuit layer PCL may function as at least some of the circuit elements, the wires, and the like. The conductive patterns may include copper, but the present disclosure is not limited thereto.

The circuit elements may include the sub-pixel circuit SPC (e.g., see FIG. 2) for each of the first to third sub-pixels SP1, SP2, and SP3. The sub-pixel circuit SPC may include the transistors and one or more capacitors. Each transistor may include a semiconductor portion including a source region, a drain region, and a channel region, and a gate electrode overlapping with the semiconductor portion. In some embodiments, when the substrate SUB is provided as a silicon substrate, the semiconductor portion may be included in the substrate SUB, and the gate electrode may be included in the pixel circuit layer PCL as a conductive pattern of the pixel circuit layer PCL. In some embodiments, when the substrate SUB is provided as a glass substrate or a PI substrate, the semiconductor portion and the gate electrode may be included in the pixel circuit layer PCL. Each capacitor may include electrodes that are spaced apart from each other. For example, each capacitor may include electrodes that are spaced apart from each other on a plane defined by the first and second directions DR1 and DR2 (e.g., in a plan view). For example, each capacitor may include electrodes that are spaced apart from each other in the third direction DR3 with an insulating layer therebetween.

The wires of the pixel circuit layer PCL may include the signal lines connected to each of the first to third sub-pixels SP1, SP2, and SP3, for example, such as a gate line, a light emitting control line, and a data line. The wires may further include the wire connected to the first power voltage node VDDN described above with reference to FIG. 2. In addition, the wires may further include the wire connected to the second power voltage node VSSN described above with reference to FIG. 2.

The light emitting element layer LDL may include anode electrodes AE, a pixel defining film PDL, a light emitting structure EMS, and a cathode electrode CE.

The anode electrodes AE may be disposed on the pixel circuit layer PCL. The anode electrodes AE may contact the circuit elements of the pixel circuit layer PCL. The anode electrodes AE may include at least one of a reflective electrode or a transparent electrode, but the present disclosure is not limited thereto.

The pixel defining film PDL is disposed on the anode electrodes AE. The pixel defining film PDL may include an opening OP exposing a portion of each of the anode electrodes AE. The openings OP of the pixel defining film PDL may be understood as light emitting areas corresponding to the first to third sub-pixels SP1 to SP3, respectively.

In some embodiments, the pixel defining film PDL may include an inorganic material. In this case, the pixel defining film PDL may include a plurality of stacked inorganic layers. For example, the pixel defining film PDL may include a silicon oxide (SiOx) and/or a silicon nitride (SiNx). In other embodiments, the pixel defining film PDL may include an organic material. However, the material of the pixel defining film PDL is not limited thereto.

The light emitting structure EMS may be disposed on the anode electrodes AE exposed by the openings OP of the pixel defining film PDL. The light emitting structure EMS may include a light emitting layer to generate light, an electron transport layer to transport electrons, and a hole transport layer to transport holes.

In some embodiments, the light emitting structure EMS may fill the openings OP of the pixel defining film PDL, and may be disposed entirely on an upper portion of the pixel defining film PDL. In other words, the light emitting structure EMS may extend across the first to third sub-pixels SP1 to SP3. In this case, at least some of the functional layers in the light emitting structure EMS may be disconnected or bent at boundaries between the first to third sub-pixels SP1 to SP3. However, the present disclosure is not limited thereto. For example, portions of the light emitting structure EMS corresponding to the first to third sub-pixels SP1 to SP3 are spaced apart (e.g., may be separated) from each other, and each of the portions may be disposed in a corresponding opening OP of the pixel defining film PDL.

The cathode electrode CE may be disposed on the light emitting structure EMS. The cathode electrode CE may extend across the first to third sub-pixels SP1 to SP3. As such, the cathode electrode CE may be provided as a common electrode for the first to third sub-pixels SP1 to SP3.

The cathode electrode CE may include (e.g., may be) a thin metal layer having a thickness sufficient to transmit light emitted from the light emitting structure EMS. The cathode electrode CE may include (e.g., may be made of) a metallic material or a transparent conductive material to have a relatively thin thickness. In some embodiments, the cathode electrode CE may include at least one of various suitable transparent conductive materials including an indium tin oxide, an indium zinc oxide, an indium tin zinc oxide, an aluminum zinc oxide, a gallium zinc oxide, a zinc tin oxide, and/or a gallium tin oxide. In other embodiments, the cathode electrode CE may include at least one of silver (Ag), magnesium (Mg), or a mixture thereof. However, the material of the cathode electrode CE is not limited thereto.

One of the anode electrodes AE, the portion of the light emitting structure EMS overlapping with the anode electrode AE, and the portion of the cathode electrode CE overlapping with the anode electrode AE may be understood to configure one light emitting element LD (e.g., see FIG. 2). In other words, each of the light emitting elements of the first to third sub-pixels SP1 to SP3 may include one anode electrode AE, a portion of the light emitting structure EMS overlapping with the one anode electrode AE, and a portion of the cathode electrode CE overlapping with the one anode electrode AE. In each of the first to third sub-pixels SP1 to SP3, holes injected from the anode electrode AE and electrons injected from the cathode electrode CE are transported into the light emitting layer of the light emitting structure EMS to form excitons, and when the excitons transition from the excited state to the ground state, light may be generated. The luminance of the light may be determined depending on the amount of current flowing through the light emitting layer. Depending on the configuration of the light emitting layer, the wavelength range of the generated light may be determined.

The encapsulation layer TFE is disposed on the cathode electrode CE. The encapsulation layer TFE may cover the light emitting element layer LDL and/or the pixel circuit layer PCL. The encapsulation layer TFE may prevent or substantially prevent oxygen and/or moisture from penetrating into the light emitting element layer LDL. In some embodiments, the encapsulation layer TFE may include a structure in which one or more inorganic films and one or more organic films are alternately stacked. For example, the inorganic film may include a silicon nitride, a silicon oxide, or a silicon oxynitride (SiOxNy). For example, the organic film may include an organic insulating material, such as an acrylic resin, an epoxy resin, a phenol resin, a polyamide resin, a polyimide resin, an unsaturated polyesters resin, a polyphenylenethers resin, a polyphenylenesulfides resin, or benzocyclobutene. However, the materials of the organic film and the inorganic film of the encapsulation layer TFE are not limited thereto.

The encapsulation layer TFE may further include a thin film including (e.g., containing) an aluminum oxide (AIOx) in order to improve an encapsulation efficiency of the encapsulation layer TFE. The thin film containing the aluminum oxide may be disposed on the upper surface of the encapsulation layer TFE facing the optical functional layer OFL, and/or on the lower surface of the encapsulation layer TFE facing the light emitting element layer LDL.

The thin film containing the aluminum oxide may be formed through atomic layer deposition (ALD). However, the present disclosure is not limited thereto. The encapsulation layer TFE may further include a thin film including (e.g., made of) at least one of various materials suitable for improving the encapsulation efficiency.

The optical functional layer OFL is disposed on the encapsulation layer TFE. The optical function layer OFL may include a color filter layer CFL and a lens array LA.

The color filter layer CFL is disposed between the encapsulation layer TFE and the lens array LA. The color filter layer CFL may selectively output light in a wavelength range or a color for each sub-pixel by filtering light emitted from the light emitting structure EMS. The color filter layer CFL includes color filters CF respectively corresponding to the first to third sub-pixels SP1 to SP3, and each of the color filters CF may pass light in a wavelength range corresponding to the corresponding sub-pixel. For example, a color filter corresponding to the first sub-pixel SP1 may pass red light, a color filter corresponding to the second sub-pixel SP2 may pass blue light, and a color filter corresponding to the third sub-pixel SP3 may pass green light. At least some of the color filters CF may be omitted according to the light (e.g., the color of light) emitted from the light emitting structure EMS of each sub-pixel.

The lens array LA is disposed on the color filter layer CFL. The lens array LA may include lenses LS respectively corresponding to the first to third sub-pixels SP1 to SP3. Each of the lenses LS may improve a light output efficiency by outputting light emitted from the light emitting structure EMS in an intended path. The lens array LA may have a relatively high refractive index. For example, the lens array LA may have a higher refractive index than that of the overcoat layer OC. In some embodiments, the lenses LS may include an organic material. In some embodiments, the lenses LS may include an acrylic material. However, the material of the lenses LS is not limited thereto.

In some embodiments, compared to the opening OP of the pixel defining film PDL, at least some of the color filters CF of the color filter layer CF and at least some of the lenses LS of the lens array LA may be shifted in a direction parallel to or substantially parallel to a plane defined by the first and second directions DR1 and DR2. In more detail, in the center area of the display area DA, the center of the color filter and the center of the lens may be aligned or overlapped with the center of the corresponding opening OP of the pixel defining film PDL when viewed in the third direction DR3 (e.g., in a plan view). For example, in the central area of the display area DA, the opening OP of the pixel defining film PDL may completely overlap with the corresponding color filter of the color filter layer CF and the corresponding lens of the lens array LA. In an area of the display area DA adjacent to the non-display area NDA, the center of the color filter and the center of the lens may be shifted in a planar direction from the center of the corresponding opening OP of the pixel defining film PDL when viewed in the third direction DR3 (e.g., in a plan view). For example, in an area of the display area DA adjacent to the non-display area NDA, the opening OP of the pixel defining film PDL may partially overlap with the corresponding color filter of the color filter layer CFL and the corresponding lens of the lens array LA. Accordingly, in the center of the display area DA, light emitted from the light emitting structure EMS may be more efficiently output in the normal direction of the display surface. Light emitted from the light emitting structure EMS at the outside of the display area DA may be more efficiently output in a direction inclined by an angle (e.g., a predetermined angle) with respect to the normal direction of the display surface.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting the lower layers thereof from foreign substances, such as dust and moisture. For example, the overcoat layer OC may include at least one of an inorganic insulating film or an organic insulating film. For example, the overcoat layer OC may include an epoxy resin, but the present disclosure is not limited thereto. The overcoat layer OC may have a lower refractive index than that of the lens array LA.

The cover window CW may be disposed on the overcoat layer OC. The cover window CW may protect the lower layers thereof. The cover window CW may have a higher refractive index than that of the overcoat layer OC. The cover window CW may include glass, but the present disclosure is not limited thereto. For example, the cover window CW may include (e.g., may be) an encapsulation glass to protect the 1 constituent elements disposed thereunder. In other embodiments, the cover window CW may be omitted as needed or desired.

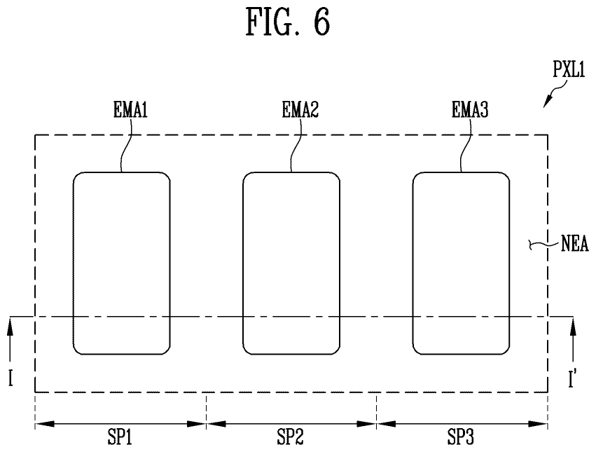

FIG. 6 illustrates a top plan view of one pixel of FIG. 5 according to an embodiment. For convenience of illustration convenience of illustration, in FIG. 6, the first pixel PXL1 from among the first and second pixels PXL1 and PXL2 described above with reference to FIG. 5 is schematically illustrated. The other remaining pixels may be configured the same or substantially the same as (or similarly to) the first pixel PXL1.

Referring to FIG. 5 and FIG. 6, the first pixel PXL1 may include the first to third sub-pixels SP1 to SP3 disposed along the first direction DR1.

The first sub-pixel SP1 may include a first light emitting area EMA1, and a non-light emitting area NEA around the first light emitting area EMA1. The second sub-pixel SP2 may include a second light emitting area EMA2, and a non-light emitting area NEA around the second light emitting area EMA2. The third sub-pixel SP3 may include a third light emitting area EMA3, and a non-light emitting area NEA around the third light emitting area EMA3.

The first light emitting area EMA1 may be an area in which light is emitted from a portion of the light emitting structure EMS (e.g., see FIG. 5) corresponding to the first sub-pixel SP1. The second light emitting area EMA2 may be an area in which light is emitted from a portion of the light emitting structure EMS corresponding to the second sub-pixel SP2. The third light emitting area EMA3 may be an area in which light is emitted from a portion of the light emitting structure EMS corresponding to the third sub-pixel SP3. As described above with reference to FIG. 5, each light emitting area may be understood as a corresponding opening OP of the pixel defining film PDL corresponding to one of the first to third sub-pixels SP1 to SP3.

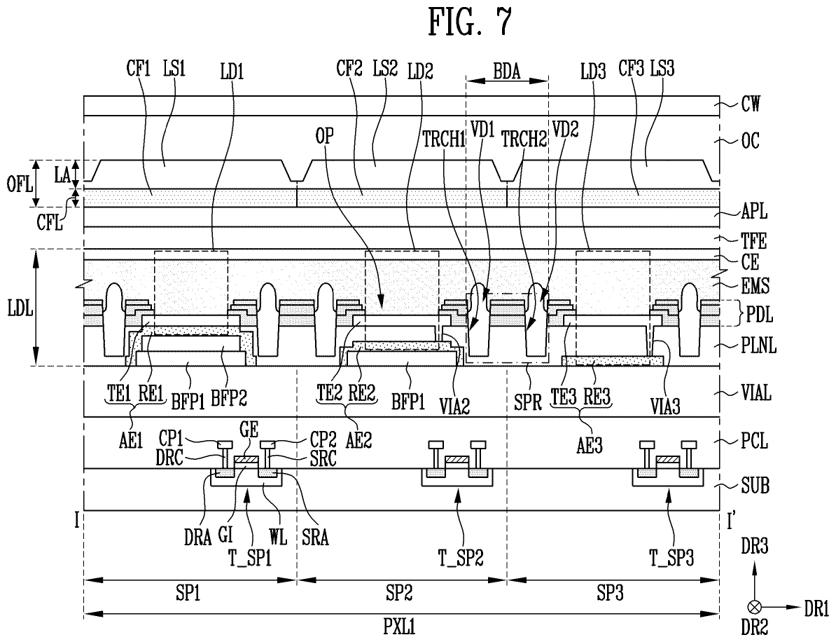

FIG. 7 illustrates a cross-sectional view taken along the line I-l′ of FIG. 6.

Referring to FIG. 7, the pixel circuit layer PCL may be disposed on the substrate SUB.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements for each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (e.g., see FIG. 2) of the first sub-pixel SP1. The transistor T_SP2 of the second sub-pixel SP2 may be one of the transistors included in the sub-pixel circuit SPC of the second sub-pixel SP2. The transistor T_SP3 of the third sub-pixel SP3 may be one of the transistors included in the sub-pixel circuit SPC of the third sub-pixel SP3. In FIG. 7, for convenience of illustration, one of the transistors of each of the sub-pixels is shown, and the other remaining circuit elements are not shown.

The transistor T_SP1 of the first sub-pixel SP1 may include a source area SRA, a drain area DRA, and a gate electrode GE.

The source area SRA and the drain area DRA may be disposed within the substrate SUB. A well WL formed through an ion injection process is disposed in the substrate SUB, and the source area SRA and the drain area DRA may be disposed to be spaced apart from each other within the well WL. The area between the source area SRA and the drain area DRA within the well WL may be defined as a channel area.

The gate electrode GE overlaps with the channel area between the source area SRA and the drain area DRA, and may be disposed at (e.g., in or on) the pixel circuit layer PCL. The gate electrode GE may be spaced apart (e.g., may be separated) from the well WL or the channel area by an insulating material, such as a gate insulating layer GI. The gate electrode GE may include a conductive material.

A plurality of layers included in the pixel circuit layer PCL may include insulating layers, and conductive patterns disposed between the insulating layers. The conductive patterns may include first and second conductive patterns CP1 and CP2. The first conductive pattern CP1 may be electrically connected to the drain area DRA through a drain connection portion DRC penetrating one or more insulating layers. The second conductive pattern CP2 may be electrically connected to the source area SRA through a source connection portion SRC penetrating one or more insulating layers.

As the gate electrode GE and the first and second conductive patterns CP1 and CP2 are connected to other circuit elements and/or wires, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured the same or substantially the same as (or similarly to) the transistor T_SP1 of the first sub-pixel SP1 described above.

As described above, the substrate SUB and the pixel circuit layer PCL may include circuit elements for each of the first to third sub-pixels SP1 to SP3.

A via layer VIAL is disposed on the pixel circuit layer PCL. The via layer VIAL covers the pixel circuit layer PCL, and may have an overall flat or substantially flat surface. The via layer VIAL may flatten steps on the pixel circuit layer PCL. The via layer VIAL may include an inorganic material. For example, the via layer VIAL may include at least one of a silicon oxide (SiOx), a silicon nitride (SiNx), or a silicon carbon nitride (SiCN), but the present disclosure is not limited thereto. The via layer VIAL may include an organic material.

The light emitting element layer LDL is disposed on the via layer VIAL. The light emitting element layer LDL may include first to third reflective electrodes RE1 to RE3, a planarization layer PLNL, first to third transparent electrodes TE1 to TE3, a pixel defining film PDL, a light emitting structure EMS, and a cathode electrode CE. A first anode electrode AE1 may include the first reflective electrode RE1 and the first transparent electrode TE1. A second anode electrode AE2 may include the second reflective electrode RE2 and the second transparent electrode TE2. A third anode electrode AE3 may include the third reflective electrode RE3 and the third transparent electrode TE3.

The first to third reflective electrodes RE1 to RE3 are disposed in the first to third sub-pixels SP1 to SP3 on the via layer VIAL, respectively. Each of the first to third reflective electrodes RE1 to RE3 may contact a corresponding circuit element disposed on the pixel circuit layer PCL through a via penetrating the via layer VIAL.

The first to third reflective electrodes RE1 to RE3 may function as full mirrors that reflect light emitted from the light emitting structure EMS toward the display surface (e.g., toward the cover window CW). The first to third reflective electrodes RE1 to RE3 may include various metallic materials suitable for reflecting light. The first to third reflective electrodes RE1 to RE3 may include at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), and/or a suitable alloy of two or more materials selected therefrom, but the present disclosure is not limited thereto.

In some embodiments, a connection electrode may be disposed below each of the first to third reflective electrodes RE1 to RE3. The connection electrode may improve electrical connection characteristics between the corresponding reflective electrode and the corresponding circuit element of the pixel circuit layer PCL. The connection electrode may have a multi-layered structure. The multi-layered structure may include titanium (Ti), a titanium nitride (TiN), a tantalum nitride (TaN), and the like, but the present disclosure is not limited thereto. In some embodiments, a 1 corresponding reflective electrode may be disposed between the multiple layers of the corresponding connecting electrode.

At least one buffer pattern BFP1 or BFP2 may be disposed below at least one of the first to third reflective electrodes RE1 to RE3. The buffer patterns BFP1 and BFP2 may include an inorganic material, such as a silicon carbon nitride, but the present disclosure is not limited thereto. By disposing the buffer patterns BFP1 and BFP2, the height of the corresponding reflective electrode in the third direction DR3 may be adjusted. For example, the first buffer pattern BFP1 and the second buffer pattern BFP2 may be disposed between the first reflective electrode RE1 and the via layer VIAL to adjust the height of the first reflective electrode RE1. The first buffer pattern BFP1 may be disposed between the second reflective electrode RE2 and the via layer VIAL to adjust a height of the second reflective electrode RE2. Accordingly, a distance between the substrate SUB and the first reflective electrode RE1, a distance between the substrate SUB and the second reflective electrode RE2, and a distance between the substrate SUB and the third reflective electrode RE3 may be different from each other. The distance may refer to a distance in the third direction DR3.

The first to third reflective electrodes RE1 to RE3 may function as full mirrors, and the cathode electrode CE may function as a half mirror. Light emitted from the light emitting layer of the light emitting structure EMS may be amplified at least partially by reciprocating between the reflective electrode and the cathode electrode CE, and the amplified light may be output through the cathode electrode CE. As such, the distance between each reflective electrode and the cathode electrode CE may be understood as the resonance distance for the light emitted from the light emitting layer of the corresponding light emitting structure EMS.

The first sub-pixel SP1 may have a shorter resonance distance than those of the second sub-pixel SP2 and the third sub-pixel SP3 due to the first buffer pattern BFP1 and the second buffer pattern BFP2. The resonance distance adjusted in this way may allow light in a desired wavelength range (e.g., a specific or predetermined 1 wavelength range) to be effectively and efficiently amplified. Accordingly, the first sub-pixel SP1 may effectively and efficiently output light in the corresponding wavelength range. The second sub-pixel SP2 may have a resonance distance that is longer than that of the first sub-pixel SP1 and shorter than that of the third sub-pixel SP3 due to the first buffer pattern BFP1. The third sub-pixel SP3 may not include a buffer pattern, and may have a longer resonance distance than those of the first sub-pixel SP1 and the second sub-pixel SP2.

In another embodiment, the third sub-pixel SP3 may include a buffer pattern. In addition, the first sub-pixel SP1 and/or the second sub-pixel SP2 may not include a buffer pattern. In other words, whether or not each sub-pixel includes a buffer pattern may be variously modified as needed or desired.

To planarize or substantially planarize the steps of the first to third reflective electrodes RE1 to RE3, the planarization layer PLNL may be disposed on the via layer VIAL and the first to third reflective electrodes RE1 to RE3. The planarization layer PLNL may entirely cover the first to third reflective electrodes RE1 to RE3 and the via layer VIAL, and may have a flat or substantially flat surface. Accordingly, a distance between the portion of the cathode electrode CE corresponding to the first light emitting element LD1 and the substrate SUB, a distance between the portion of the cathode electrode CE corresponding to the second light emitting element LD2 and the substrate SUB, and a distance between the portion of the cathode electrode CE corresponding to the third light emitting element LD3 and the substrate SUB may be the same or substantially the same as each other.

In some embodiments, at least a portion of the planarization layer PLNL may be omitted as needed or desired. In an embodiment, the planarization layer PLNL may not exist on at least one reflective electrode (for example, such as on the first reflective electrode RE1).

The first to third transparent electrodes TE1 to TE3 overlapping with the first to third reflective electrodes RE1 to RE3, respectively, may be disposed on the 1 planarization layer PLNL. The first to third transparent electrodes TE1 to TE3 may have shapes that are the same or substantially the same as (or similar to) those of the first to third light emitting areas EMA1 to EMA3 described above with reference to FIG. 6 when viewed in the third direction DR3 (e.g., in a plan view). The first to third transparent electrodes TE1 to TE3 may be connected to the first to third reflective electrodes RE1 to RE3, respectively. The first transparent electrode TE1 may be directly connected to the first reflective electrode RE1. In another example, the first transparent electrode TE1 may be connected to the first reflective electrode RE1 through a first via penetrating the planarization layer PLNL. The second transparent electrode TE2 may be connected to the second reflective electrode RE2 through a second via VIA2 penetrating the planarization layer PLNL. The third transparent electrode TE3 may be connected to the third reflective electrode RE3 through a third via VIA3 penetrating the planarization layer PLNL.

In some embodiments, the first to third transparent electrodes TE1 to TE3 may include at least one of various suitable transparent conductive materials, such as an indium tin oxide (ITO), an indium zinc oxide (IZO), a zinc oxide (ZnOx), an indium gallium zinc oxide (IGZO), and/or an indium tin zinc oxide (ITZO). However, the materials of the first to third transparent electrodes TE1 to TE3 are not limited thereto. For example, the first to third transparent electrodes TE1 to TE3 may include a titanium nitride.

In some embodiments, insulating layers for adjusting a height of one or more of the first to third transparent electrodes TE1 to TE3 may be further provided. The insulating layers may be disposed between one or more of the first to third transparent electrodes TE1 to TE3 and the corresponding reflective electrodes. In this case, the planarization layer PLNL and/or the buffer pattern BFP may be omitted as needed or desired.

The pixel defining film PDL is disposed on some of the first to third transparent electrodes TE1 to TE3 and the planarization layer PLNL. The pixel 1 defining film PDL may include an openings OP exposing a portion of each of the first to third transparent electrodes TE1 to TE3. The openings OP of the pixel defining film PDL may define the light emitting area for each of the first to third sub-pixels SP1 to SP3. As such, the pixel defining film PDL may be disposed in the non-light emitting area NEA described above with reference to FIG. 6 to define the first to third light emitting areas EMA1 to EMA3.

In some embodiments, the pixel defining film PDL may include a plurality of inorganic insulating layers. Each of the plurality of inorganic insulating layers may include at least one of a silicon oxide (SiOx) or a silicon nitride (SiNx). For example, the pixel defining film PDL may include first to third inorganic insulating layers that are sequentially stacked, and each of the first to third inorganic insulating layers may include a silicon nitride, a silicon oxide, and/or a silicon oxynitride. However, the present disclosure is not limited thereto. The first to third inorganic insulating layers may have a step-shaped cross-section in an area adjacent to the opening OP. In an embodiment, the pixel defining film PDL may include an organic material.

A separator SPR may be provided in the boundary area BDA between the sub-pixels that are adjacent to each other. In other words, the separator SPR may be provided in each of the boundary areas between the sub-pixels SP described above with reference to FIG. 4.

The separator SPR may cause a discontinuity to be formed within the light emitting structure EMS in the boundary area BDA. For example, the light emitting structure EMS may be disconnected or bent in the boundary area BDA by the separator SPR.

The separator SPR may be provided at (e.g., in or on) the pixel defining film PDL. The pixel defining film PDL may include one or more trenches TRCH1 and TRCH2 as the separator SPR in the boundary area BDA. In some embodiments, as shown in FIG. 7, the one or more trenches TRCH1 and TRCH2 may penetrate the pixel defining film PDL, and may partially penetrate the planarization layer PLNL. In other embodiments, the one or more trenches TRCH1 and TRCH2 may penetrate the pixel defining film PDL and the planarization layer PLNL, and may partially penetrate the via layer VIAL. In another embodiment, the one or more trenches TRCH1 and TRCH2 may partially penetrate the pixel defining film PDL. In other embodiments, the one or more trenches TRCH1 and TRCH2 may at least partially penetrate the planarization layer PLNL and/or the via layer VIAL, and a portion of the pixel defining film PDL may be disposed in the one or more trenches TRCH1 and TRCH2.

FIG. 7 illustrates two trenches TRCH1 and TRCH2 provided in the boundary region BDA. However, the present disclosure is not limited thereto. For example, the pixel defining film PDL may include one trench in the boundary area BDA. As another example, the pixel defining film PDL may include three or more trenches in the boundary area BDA.

Due to the first and second trenches TRCH1 and TRCH2, discontinuous portions, such as a first void VD1 and a second void VD2, may be formed in the light emitting structure EMS in the boundary area BDA. Some of the plurality of layers stacked in the light emitting structure EMS may be disconnected or bent by the first and second voids VD1 and VD2. For example, at least one charge generation layer included in the light emitting structure EMS may be disconnected in the first and second voids VD1, and VD2. As described above, due to the first and second trenches TRCH1 and TRCH2, the portions of the light emitting structure EMS included in the first to third sub-pixels SP1 to SP3 may be at least partially spaced apart (e.g., may be at least partially separated) from each other.

FIG. 7 shows that the first and second voids VD1 and VD2 are formed in the light emitting structure EMS in the boundary area BDA, but the present disclosure is not limited thereto. For example, a valley having a concave shape may be formed in the light emitting structure EMS in the boundary area BDA. Depending on the shapes of the first and second trenches TRCH1 and TRCH2, the discontinuities formed in the light emitting structure EMS may be variously modified as needed or desired.

In some embodiments, the light emitting structure EMS may be formed through various suitable processes, such as a vacuum deposition or an inkjet printing. In this case, the same materials as those of the light emitting structure EMS may be disposed on the bottom surfaces of the first and second trenches TRCH1 and TRCH2 that are adjacent to the via layer VIAL.

The separator SPR may be variously deformed to allow the light emitting structure EMS to be able to have a discontinuity in the boundary area BDA. In some embodiments, inorganic insulating patterns additionally stacked on the pixel defining film PDL in the boundary area BDA may be provided without the first and second trenches TRCH1 and TRCH2. A width of the uppermost inorganic insulating pattern from among the additionally stacked inorganic insulating patterns may be greater than a width of the inorganic insulating pattern disposed directly below the uppermost inorganic insulating pattern. For example, in the boundary area BDA, the first to third inorganic insulating patterns may be sequentially stacked from the pixel defining film PDL, and an uppermost third inorganic insulating pattern may have a larger width than that of the second inorganic insulating pattern. For example, the pixel defining film PDL may have a cross-section of a “T” shape or an “I” shape in the boundary area BDA. Depending on the shape of the pixel defining film PDL, a plurality of layers included in the light emitting structure EMS may be at least partially disconnected or bent in the boundary area BDA.

The light emitting structure EMS may be disposed on the anode electrodes AE exposed by the openings OP of the pixel defining film PDL. The light emitting structure EMS may fill the openings OP of the pixel defining film PDL, and may be disposed entirely across the first to third sub-pixels SP1 to SP3. As described above, the light emitting structure EMS may be at least partially disconnected or bent in the boundary area BDA by the separator SPR. Accordingly, when the display panel DP operates, the current leaking from each of the first to third sub-pixels SP1 to SP3 to the neighboring sub-pixel through the layers included in the light emitting structure EMS 1 may be decreased. Accordingly, the first to third light emitting elements LD1 to LD3 may operate with a relatively high reliability.

The cathode electrode CE may be disposed on the light emitting structure EMS. The cathode electrode CE may be provided commonly for the first to third sub-pixels SP1 to SP3. The cathode electrode CE may function as a half mirror that partially transmits and partially reflects light emitted from the light emitting structure EMS.

The first anode electrode AE1, the portion of the light emitting structure EMS overlapping with the first anode electrode AE1, and the portion of the cathode electrode CE overlapping with the first anode electrode AE1 may configure the first light emitting element LD1. The second anode electrode AE2, the portion of the light emitting structure EMS overlapping with the second anode electrode AE2, and the portion of the cathode electrode CE overlapping with the second anode electrode AE2 may configure the second light emitting element LD2. The third anode electrode AE3, the portion of the light emitting structure EMS overlapping with the third anode electrode AE3, and the portion of the cathode electrode CE overlapping with the third anode electrode AE3 may configure the third light emitting element LD3.

The encapsulation layer TFE is disposed on the cathode electrode CE. The encapsulation layer TFE may prevent or substantially prevent oxygen and/or moisture from penetrating into the light emitting element layer LDL.

The optical functional layer OFL is disposed on the encapsulation layer TFE. In some embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting the lower layers thereof including the encapsulation layer TFE.

The optical functional layer OFL may include a color filter layer CFL and a lens array LA. The color filter layer CFL may include first to third color filters CF1 to CF3 corresponding to the first to third sub-pixels SP1 to SP3, respectively. The first to third color filters CF1 to CF3 may pass light in different wavelength ranges from each other. For example, the first to third color filters CF1 to CF3 may pass red, blue, and green colored light, respectively.

In some embodiments, the first to third color filters CF1 to CF3 may partially overlap with each other in the boundary area BDA. In other embodiments, the first to third color filters CF1 to CF3 may be spaced apart from each other, and a black matrix may be provided between the first to third color filters CF1 to CF3.

The lens array LA is disposed on the color filter layer CFL. The lens array LA may include first to third lenses LS1 to LS3 corresponding to the first to third sub-pixels SP1 to SP3, respectively. The first to third lenses LS1 to LS3 may improve a light output efficiency by outputting the light emitted from the first to third light emitting elements LD1 to LD3, respectively, along an intended path.

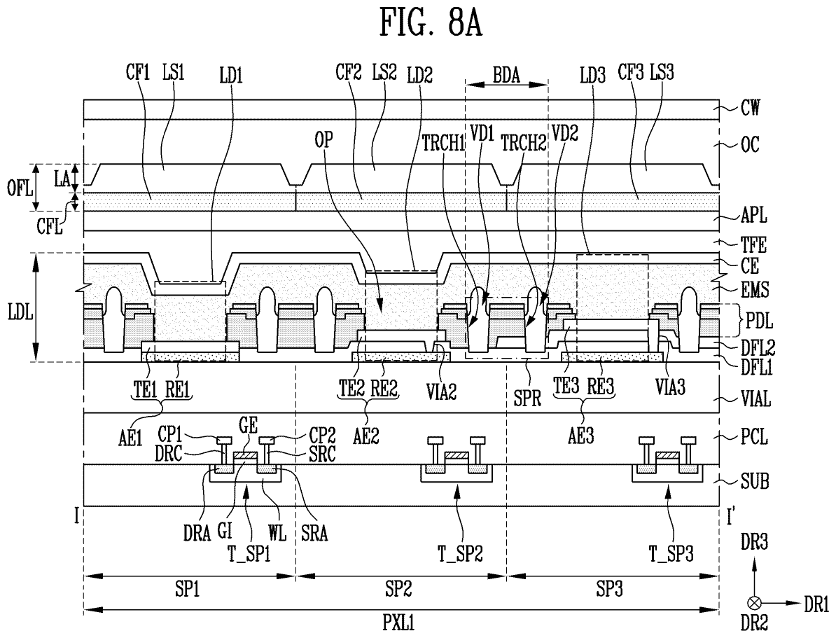

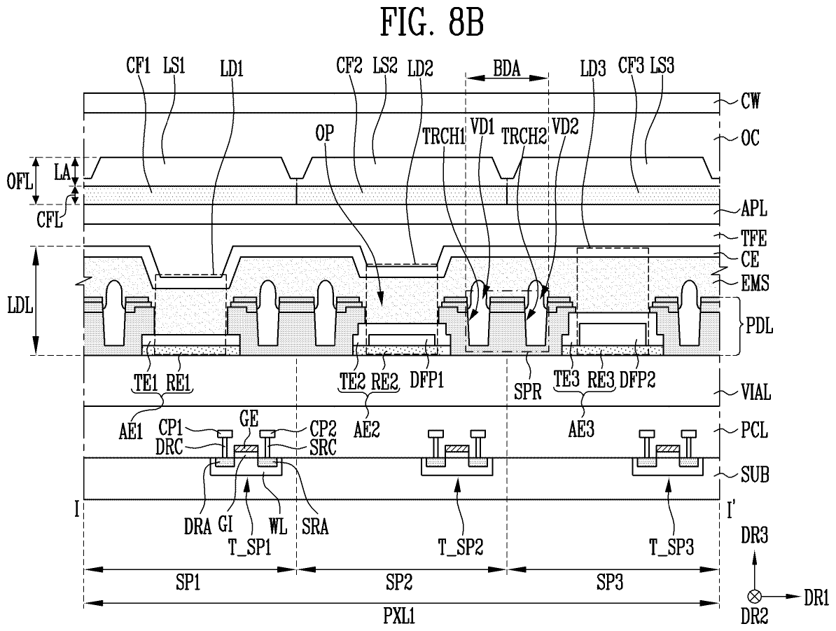

FIG. 8A and FIG. 8B illustrate cross-sectional views taken along the line I-I′ of FIG. 6 according to one or more embodiments. Hereinafter with reference to FIG. 8A and FIG. 8B, redundant description as those described above with reference to FIG. 7 may not be repeated.

In FIG. 8A, unlike the light emitting element layer LDL described above with reference to FIG. 7, the light emitting element layer LDL may not include the planarization layer PLNL and the buffer patterns BFP1 and BFP2. Referring to FIG. 8A, the light emitting element layer LDL may include at least one differential film DFL1 or DFL2.

The first to third reflective electrodes RE1, RE2, and RE3 may be disposed on the via layer VIAL. Because there may be no buffer pattern below the first to third reflective electrodes RE1, RE2, and RE3, the distance between the substrate SUB and the first reflective electrode RE1, the distance between the substrate SUB and the second reflective electrode RE2, and the distance between the substrate SUB and the third reflective electrode RE3 may be the same or substantially the same as each other. The distance may refer to a distance in the third direction DR3.

The at least one differential film DFL1 or DFL2 may be disposed on at least one of the first to third reflective electrodes RE1 to RE3. For example, the first differential film DFL1 may be disposed on the second reflective electrode RE2 and the third reflective electrode RE3. The second differential film DFL2 may be disposed on the third reflective electrode RE3. Each of the differential films DFL1 and DFL2 may include at least one of a silicon oxide (SiOx) or a silicon nitride (SiNx), but the present disclosure is not limited thereto.

The differential films DFL1 and DFL2 may adjust a height of the cathode electrode CE in the third direction DR3. Accordingly, the distance between the portion of the cathode electrode CE corresponding to the first light emitting element LD1 and the substrate SUB, the distance between the portion of the cathode electrode CE corresponding to the second light emitting element LD2 and the substrate SUB, and the distance between the portion of the cathode electrode CE corresponding to the third light emitting element LD3 and the substrate SUB may be different from each other.

For example, the first sub-pixel SP1 may not include a differential film, so that the first sub-pixel SP1 may have a shorter resonance distance than those of the second sub-pixel SP2 and the third sub-pixel SP3. The second sub-pixel SP2 may have a resonance distance that is longer than that of the first sub-pixel SP1 and shorter than that of the third sub-pixel SP3 due to the first differential film DFL1. The third sub-pixel SP3 may have a longer resonance distance than those of the first sub-pixel SP1 and the second sub-pixel SP2 due to the first and second differential films DFL1 and DFL2.

In another embodiment, the first sub-pixel SP1 may include at least one differential film DFL1 or DFL2. In addition, the second sub-pixel SP2 and the third sub-pixel SP3 may not to include a differential film. In other words, whether or not each sub-pixel includes a differential film may be variously modified as needed or desired.

The first to third transparent electrodes TE1 to TE3 may be respectively connected to the first to third reflective electrodes RE1 to RE3. The first transparent electrode TE1 may be directly connected to the first reflective electrode RE1. In another example, the first transparent electrode TE1 may be connected to the first reflective electrode RE1 through a first via penetrating the differential film (e.g., the first or second differential film DFL1 or DFL2). The second transparent electrode TE2 may be connected to the second reflective electrode RE2 through a second via VIA2 penetrating the first differential film DFL1. The third transparent electrode TE3 may be connected to the third reflective electrode RE3 through a third via VIA3 penetrating the first differential film DFL1 and the second differential film DFL2.

In FIG. 8B, unlike the light emitting element layer LDL described above with reference to FIG. 8A, the light emitting element layer LDL may not include the differential films DFL1 and DFL2. Referring to FIG. 8B, the light emitting element layer LDL may include at least one differential pattern DFP1 or DFP2.

The at least one differential pattern DFP1 or DFP2 may be disposed on at least one of the first to third reflective electrodes RE1 to RE3. For example, the first differential pattern DFP1 may be disposed on the second reflective electrode RE2. The second differential pattern DFP2 may be disposed on the third reflective electrode RE3. Each of the differential patterns DFP1 and DFP2 may include at least one of a silicon oxide (SiOx) or a silicon nitride (SiNx), but the present disclosure is not limited thereto.

Each of the differential patterns DFP1 and DFP2 may have an island shape, and may have a shape that is the same or substantially the same as (or similar to) the corresponding opening OP of the pixel defining film PDL in a plan view. For example, each of the differential patterns DFP1 and DFP2 may be positioned within the corresponding opening OP of the pixel defining layer PDL in a plan view. For example, the differential patterns DFP1 and DFP2 may overlap with the corresponding openings OP of the pixel defining film PDL in the third direction DR3, but may not overlap with the pixel defining film PDL in the third direction DR3.

The differential patterns DFP1 and DFP2 may adjust a height of the cathode electrode CE in the third direction DR3. For example, the thickness (e.g., the height) of the second differential pattern DFP2 may be greater than that of the first differential pattern DFP1. Accordingly, the distance between the portion of the cathode electrode CE corresponding to the first light emitting element LD1 and the substrate SUB, the distance between the portion of the cathode electrode CE corresponding to the second light emitting element LD2 and the substrate SUB, and the distance between the portion of the cathode electrode CE corresponding to the third light emitting element LD3 and the substrate SUB may be different from each other.

For example, the first sub-pixel SP1 may not include a differential pattern, so that the first sub-pixel SP1 may have a shorter resonance distance than those of the second sub-pixel SP2 and the third sub-pixel SP3. The second sub-pixel SP2 may have a resonance distance that is longer than that of the first sub-pixel SP1 and shorter than that of the third sub-pixel SP3 due to the first differential pattern DFP1. The third sub-pixel SP3 may have a longer resonance distance than those of the first sub-pixel SP1 and the second sub-pixel SP2 due to the second differential pattern DFL2.

In another embodiment, the first sub-pixel SP1 may include at least one differential pattern DFP1 or DFP2. In addition, the second sub-pixel SP2 and the third sub-pixel SP3 may not include a differential pattern. In other words, whether or not each sub-pixel includes a differential pattern may be variously modified as needed or desired.

The first to third transparent electrodes TE1 to TE3 may be respectively connected to the first to third reflective electrodes RE1 to RE3. The first transparent electrode TE1 may cover the first reflective electrode RE1, and a lower surface of the first transparent electrode TE1 may be connected to an upper surface of the first reflective electrode RE1. The second transparent electrode TE2 may cover the first differential pattern DFP1, and at least a portion of an edge of a lower surface of the second transparent electrode TE2 may be connected to the second reflective electrode RE2. The third transparent electrode TE3 may cover the second differential pattern DFP2, and at least a portion of an edge of a lower surface of the third transparent electrode TE3 may be connected to the third reflective electrode RE3.

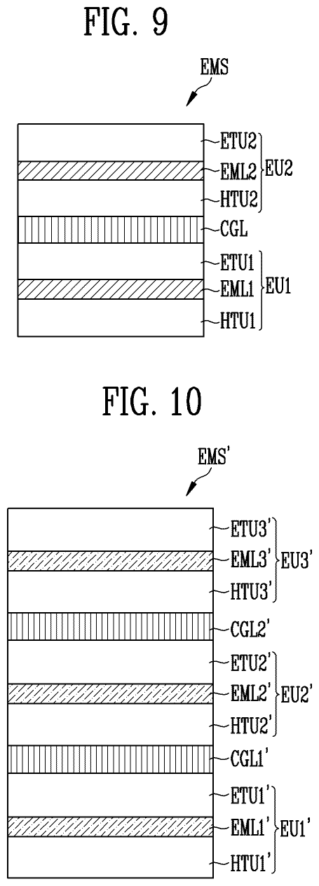

FIG. 9 illustrates a cross-sectional view of a light emitting structure included in one light emitting element according to an embodiment. FIG. 9 illustrates the light emitting structure of one of the first to third light emitting elements described above with reference to FIG. 7, FIG. 8A, and FIG. 8B according to an embodiment.

Referring to FIG. 9, the light emitting structure EMS may have a tandem structure in which first and second light emitting portions EU1 and EU2 are stacked. The light emitting structure EMS may be configured to be the same or substantially the same in each of the first to third light emitting elements LD1 to LD3 described above with reference to FIG. 7, FIG. 8A, and FIG. 8B.

Each of the first and second light emitting portions EU1 and EU2 may include at least one light emitting layer that generates light according to a current applied thereto. The first light emitting portion EU1 may include a first light emitting layer EML1, a first electron transport portion ETU1, and a first hole transport portion HTU1. The first light emitting layer EML1 may be disposed between the first electron transport portion ETU1 and the first hole transport portion HTU1. The second light emitting portion EU2 may include a second light emitting layer EML2, a second electron transport portion ETU2, and a second hole transport portion HTU2. The second light emitting layer EML2 may be disposed between the second electron transport portion ETU2 and the second hole transport portion HTU2.

Each of the first and second hole transport portions HTU1 and HTU2 may include at least one of a hole injection layer or a hole transport layer, and may further include a hole buffer layer, an electron blocking layer, or the like as needed or desired. The first and second hole transport portions HTU1 and HTU2 may have the same or substantially the same configuration as each other, or may have different configurations from each other.

Each of the first and second electron transport portions ETU1 and ETU2 may include at least one of an electron injection layer or an electron transport layer, and may further include an electron buffer layer and a hole blocking layer as needed or desired. The first and second electron transport portions ETU1 and ETU2 may have the same or substantially the same configuration as each other, or may have different configurations from each other.

A connection layer, which may be provided in the form of a charge generation layer CGL, may be disposed between the first light emitting portion EU1 and the second light emitting portion EU2 to connect them to each other. In some embodiments, the charge generation layer CGL may have a sequential stacked structure of an n dopant layer and a p dopant layer. The n dopant layer may be an electron generation layer. The p dopant layer may be a hole generation layer. For example, the n dopant layer of the charge generation layer CGL may be disposed on the first electron transport portion ETU1, the p dopant layer of the charge generation layer CGL may be disposed on the n dopant layer, and the second hole transport portion HTU2 may be disposed on the p dopant layer. For example, the n dopant layer may include an alkali metal, an alkaline earth metal, a lanthanide metal, or a suitable combination thereof, and the p dopant layer may include a p-type dopant, such as HAT-CN, TCNQ, or NDP-9. However, the present disclosure is not limited thereto.

In some embodiments, the first light emitting layer EML1 and the second light emitting layer EML2 may generate light of different colors from each other. The light emitted from each of the first light emitting layer EML1 and the second light emitting layer EML2 may be mixed together to be recognized as white light. For example, the first light emitting layer EML1 may generate a blue-colored light, and the second light emitting layer EML2 may generate a yellow-colored light. In some embodiments, the second light emitting layer EML2 may include a structure in which a first sub-light-emitting layer configured to generate red-colored light and a second sub-light-emitting layer configured to generate green-colored light are stacked. The red-colored light and the green-colored light may be mixed together to provide yellow-colored light. In this case, an intermediate layer for transporting holes and/or for preventing or substantially preventing the transport of electrons may be further disposed between the first and second sub-light emitting layers.

In other embodiments, the first light emitting layer EML1 and the second light emitting layer EML2 may generate light of the same or substantially the same color as each other.

The light emitting structure EMS may be formed through a vacuum deposition method, an inkjet printing method, or the like, but the present disclosure is not limited thereto.

The first light emitting portion EU1 and the charge generation layer CGL may be disconnected by the separator SPR (e.g., see FIG. 7, FIG. 8A, or FIG. 8B). In some embodiments, at least a portion of the second light emitting portion EU2 may be disconnected by the separator SPR. Accordingly, a leakage current through a common layer between adjacent sub-pixels may be prevented or substantially prevented. The cathode electrode CE may be extended on an upper portion of the separator SPR without disconnection (e.g., without being disconnected).

FIG. 10 illustrates a cross-sectional view of a light emitting structure included in one light emitting element according to an embodiment. FIG. 10 illustrates the light emitting structure included in one of the first to third light emitting elements of FIG. 7, FIG. 8A, and FIG. 8B according to an embodiment.

Referring to FIG. 10, the light emitting structure EMS' may have a tandem structure in which first to third light emitting portions EU1′ to EU3′ are stacked. The light emitting structure EMS' may be configured to be the same or substantially the same in each of the first to third light emitting elements LD1 to LD3 described above with reference to FIG. 7, FIG. 8A, and FIG. 8B.

Each of the first to third light emitting portions EU1′ to EU3′ may include a light emitting layer that generates light according to a current applied thereto. The first light emitting portion EU1′ may include a first light emitting layer EML1′, a first electron transport portion ETU1′, and a first hole transport portion HTU1′. The first light emitting layer EML1′ may be disposed between the first electron transport portion ETU1′ and the first hole transport portion HTU1′. The second light emitting portion EU2′ may include a second light emitting layer EML2′, a second electron transport portion ETU2′, and a second hole transport portion HTU2′. The second light emitting layer EML2′ may be disposed between the second electron transport portion ETU2′ and the second hole transport portion HTU2′. The third light emitting portion EU3′ may include a third light emitting layer EML3′, a third electron transport portion ETU3′, and a third hole transport portion HTU3′. The third light emitting layer EML3′ may be disposed between the third electron transport portion ETU3′ and the third hole transport portion HTU3′.

Each of the first to third hole transport portions HTU1′ to HTU3′ may include at least one of a hole injection layer or a hole transport layer, and may further include a hole buffer layer, an electron blocking layer, or the like as needed or desired. The first to third hole transport portions HTU1′ to HTU3′ may have the same or substantially the same configuration as each other, or may have different configurations from each other.

Each of the first to third electron transport portions ETU1′ to ETU3′ may include at least one of an electron injection layer or an electron transport layer, and may further include an electron buffer layer and a hole blocking layer as needed or desired. The first to third electron transport portions ETU1′ to ETU3′ may have the same or substantially the same configuration as each other, or may have different configurations from each other.

A first charge generation layer CGL1′ is disposed between the first light emitting portion EU1′ and the second light emitting portion EU2′. A second charge generation layer CGL2′ is disposed between the second light emitting portion EU2′ and the third light emitting portion EU3′.

In some embodiments, the first to third light emitting layers EML1′ to EML3′ may generate light of different colors from each other. Light emitted from each of the first to third light emitting layers EML1′ to EML3′ may be mixed together to be viewed as white light. For example, the first light emitting layer EML1′ may generate light of a blue color, the second light emitting layer EML2′ may generate light of a green color, and the third light emitting layer EML3′ may generate light of a red color.

In other embodiments, two or more of the first to third light emitting layers EML1′ to EML3′ may generate light of the same color as each other.

In some embodiments, unlike those described above with reference to FIG. 9 and FIG. 10, the light emitting structure EMS described above with reference to FIG. 7, FIG. 8A, or FIG. 8B may include one light emitting portion in each of the first to third light emitting elements LD1 to LD3. In this case, the light emitting portions included in the first to third light emitting elements LD1 to LD3, respectively, may emit light of different colors from each other. For example, the light emitting portion of the first light emitting element LD1 may emit a red-colored light, the light emitting portion of the second light emitting element LD2 may emit a blue-colored light, and the light emitting portion of the third light emitting element LD3 may emit a green-colored light. In this case, unlike those described above with reference to FIG. 7, FIG. 8A, or FIG. 8B, the light emitting portions of the first to third sub-pixels SP1 to SP3 may be spaced apart (e.g., may be separated) from each other, and each of the light emitting portions may be disposed in the corresponding opening OP of the pixel defining film PDL. In this case, at least some of the color filters CF1 to CF3 may be omitted as needed or desired.

The first light emitting portion EU1′, the first charge generation layer CGL1′, the second light emitting portion EU2′, and the second charge generation layer CGL2′ may be disconnected by the separator SPR (e.g., see FIG. 7, FIG. 8A, or FIG. 8B). In some embodiments, at least a portion of the third light emitting portion EU3′ may be disconnected by the separator SPR. Accordingly, a leakage current through a common layer between adjacent sub-pixels may be prevented or substantially prevented. The cathode electrode CE may be extended on an upper portion of the separator SPR without disconnection (e.g., without being disconnected).

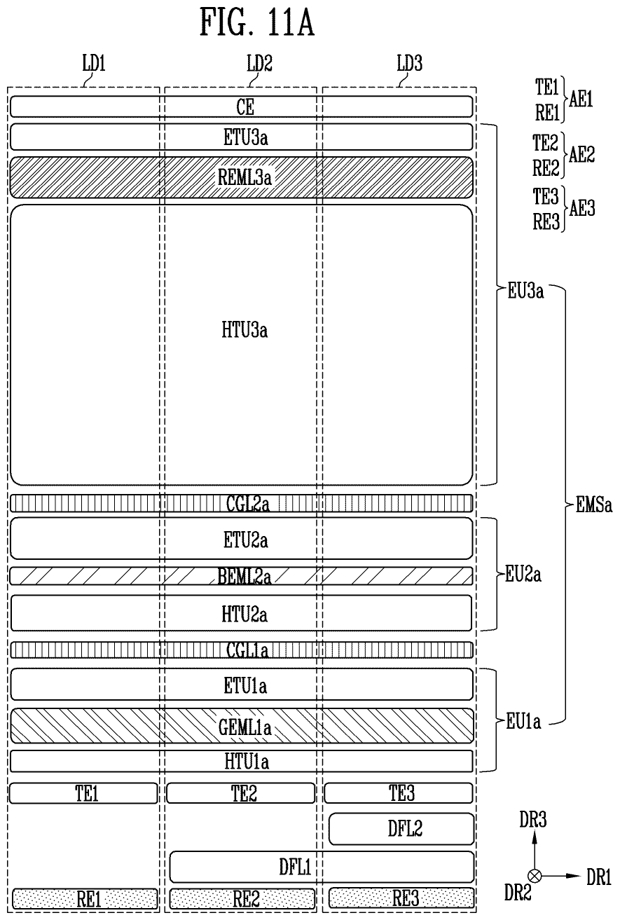

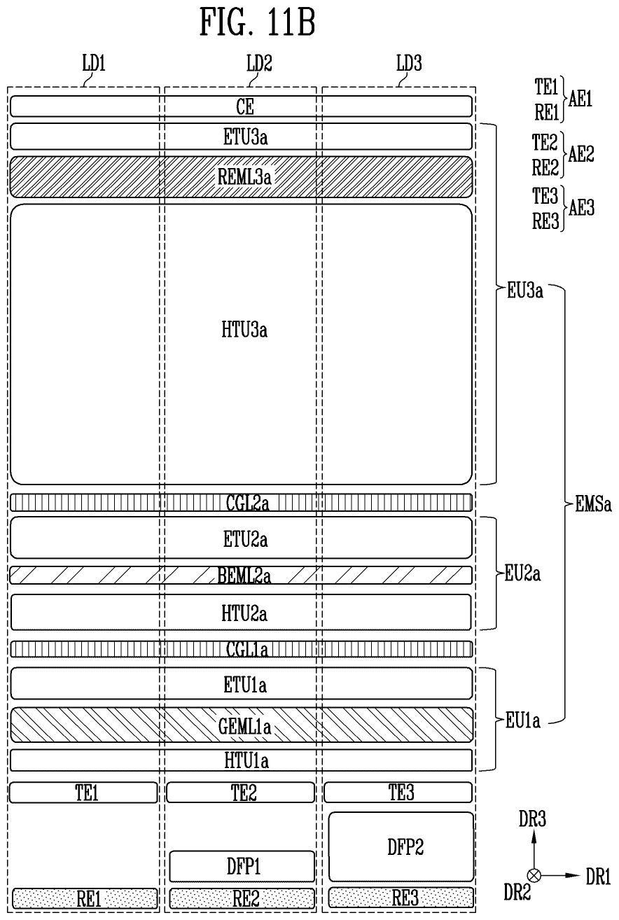

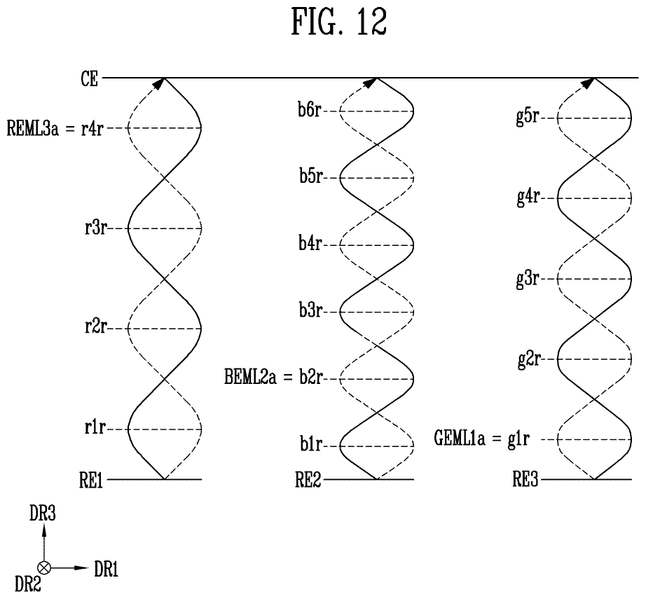

FIG. 11A illustrates first to third light emitting elements according to an embodiment of the present disclosure. FIG. 11B illustrates first to third light emitting elements according to an embodiment of the present disclosure. FIG. 12 illustrates first to third light emitting elements according to an embodiment of the present disclosure.

Referring to FIG. 11A and FIG. 11B, the first light emitting element LD1 disposed on the first reflective electrode RE1, the second light emitting element LD2 disposed on the second reflective electrode RE2, and the third light emitting element LD3 disposed on the third reflective electrode RE3 are illustrated.

The first light emitting element LD1, the second light emitting element LD2, and the third light emitting element LD3 may share the light emitting structure EMSa and the cathode electrode CE. The light emitting structure EMSa may include a first light emitting portion EU1a, a second light emitting portion EU2a, and a third light emitting portion EU3a, which are sequentially stacked. The stacked structure of the light emitting structure EMSa may be the same or substantially the same as the stacked structure of the light emitting structure EMS' described above with reference to FIG. 10.

For example, the first light emitting portion EU1a may include a first hole transport portion HTU1a, a first light emitting layer GEML1a, and a first electron transport portion ETU1a. The first light emitting layer GEML1a may be disposed between the first hole transport portion HTU1a and the first electron transport portion ETU1a. The second light emitting portion EU2a may include a second hole transport portion HTU2a, a second light emitting layer BEML2a, and a second electron transport portion ETU2a. The second light emitting layer BEML2a may be disposed between the second hole transport portion HTU2a and the second electron transport portion ETU2a. The third light emitting portion EU3a may include a third hole transport portion HTU3a, a third light emitting layer REML3a, and a third electron transport portion ETU3a. The third light emitting layer REML3a may be disposed between the third hole transport portion HTU3a and the third electron transport portion ETU3a. The first charge generation layer CGL1a may be disposed between the first light emitting portion EU1a and the second light emitting portion EU2a. The second charge generation layer CGL2a may be disposed between the second light emitting portion EU2a and the third light emitting portion EU3a.

As described above, the separator SPR may disconnect the first light emitting portion EU1a, the first charge generation layer CGL1a, the second light emitting portion EU2a, and the second charge generation layer CGL2a, thereby preventing or substantially preventing a leakage current through a common layer between adjacent sub-pixels. In addition, the separator SPR may disconnect at least a portion of the third light emitting portion EU3a. However, the separator SPR may not disconnect the cathode electrode CE, which is a common electrode. When the cathode electrode CE is disconnected by the separator SPR, the second power voltage VSS of the second power voltage node VSSN may not be transmitted to the cathode electrode CE of the light emitting elements LD1, LD2, and LD3, or an IR drop (a voltage drop) of the second power voltage VSS may occur.

In the present embodiment, the thickness (e.g., in the third direction DR3) of the third light emitting portion EU3a may be greater than the sum of the thicknesses (e.g., in the third direction DR3) of the first light emitting portion EU1a and the second light emitting portion EU2a. For example, the thickness of the third hole transport portion HTU3a included in the third light emitting portion EU3a may be greater than the sum of the thicknesses of the first light emitting portion EU1a and the second light emitting portion EU2a. The thickness may refer to a length in the third direction DR3.

For example, the thickness of the third light emitting portion EU3a may be 2.5 times or more than the sum of the thickness of the first light emitting portion EU1a and the thickness of the second light emitting portion EU2a. For example, the thickness of the third hole transport portion HTU3a included in the third light emitting portion EU3a may be 2.5 times or more than the sum of the thicknesses of the first light emitting portion EU1a and the second light emitting portion EU2a. For example, the thickness of the third light emitting portion EU3a may correspond to about 2.65 times the sum of the thickness of the first light emitting portion EU1a, the thickness of the first charge generation layer CGL1a, and the thickness of the second light emitting portion EU2a.

According to the present embodiment, while the first light emitting portion EU1a, the first charge generation layer CGL1a, the second light emitting portion EU2a, and the second charge generation layer CGL2a are disconnected by the separator SPR, the cathode electrode CE may not be disconnected by the separator SPR.

In this case, the thickness of the third light emitting portion EU3a or the thickness of the third hole transport portion HTU3a may be increased (e.g., may be continuously increased), but a power consumption for emitting light with the same or substantially the same luminance may be increased, and it may be difficult to match the resonance distance. Hereinafter, configurations for adjusting the resonance distance according to the above-described thickness conditions will be described in more detail.

In the embodiments illustrated in FIG. 11A, FIG. 11B, and FIG. 12, the first light emitting layer GEML1a may emit green light. The second light emitting layer BEML2a may emit blue light. The third light emitting layer REML3a may emit red light.

For example, the first color filter CF1 that allows red light to pass may be disposed on an upper portion of the first light emitting element LD1 (e.g., see FIG. 7, FIG. 8A, or FIG. 8B). In this case, the first light emitting element LD1 is an element for emitting red light, and it may be desired for the resonance distance between the cathode electrode CE and the first reflective electrode RE1 to be set to be suitable so that the red light emitted from the third light emitting layer REML3a interferes constructively. The second color filter CF2 that allows blue light to pass may be disposed on an upper portion of the second light emitting element LD2. In this case, the second light emitting element LD2 is an element for emitting blue light, and it may be desired for the resonance distance between the cathode electrode CE and the second reflective electrode RE2 to be set to be suitable so that the blue light emitted from the second light emitting layer BEML2a interferes constructively. The third color filter CF3 that allows green light to pass may be disposed on an upper portion of the third light emitting element LD3. In this case, the third light emitting element LD3 is an element for emitting green light, and it may be desired to set the resonance distance between the cathode electrode CE and the third reflective electrode RE3 to be suitable so that the green light emitted from the first light emitting layer GEML1a interferes constructively.

Referring to FIG. 11A, as described above with reference to FIG. 8A, a differential film may not exist between the first transparent electrode TE1 and the first reflective electrode RE1 of the first light emitting element LD1. The first differential film DFL1 may exist between the second transparent electrode TE2 and the second reflective electrode RE2 of the second light emitting element LD2. The first differential film DFL1 and the second differential film DFL2 may exist between the third transparent electrode TE3 and the third reflective electrode RE3 of the third light emitting element LD3. Accordingly, the distance between the first transparent electrode TE1 and the first reflective electrode RE1 may be smaller than that between the second transparent electrode TE2 and the second reflective electrode RE2. In addition, the distance between the second transparent electrode TE2 and the second reflective electrode RE2 may be smaller than that between the third transparent electrode TE3 and the third reflective electrode RE3.

Referring to FIG. 11B, as described above with reference to FIG. 8B, a differential pattern may not exist between the first transparent electrode TE1 and the first reflective electrode RE1 of the first light emitting element LD1. The first differential pattern DFP1 may exist between the second transparent electrode TE2 and the second reflective electrode RE2 of the second light emitting element LD2. The second differential pattern DFP2 may exist between the third transparent electrode TE3 and the third reflective electrode RE3 of the third light emitting element LD3. The length of the second differential pattern DFP2 in the third direction DR3 may be greater than that of the first differential pattern DFP1 in the third direction DR3. Accordingly, the distance between the first transparent electrode TE1 and the first reflective electrode RE1 may be smaller than that between the second transparent electrode TE2 and the second reflective electrode RE2. In addition, the distance between the second transparent electrode TE2 and the second reflective electrode RE2 may be smaller than that between the third transparent electrode TE3 and the third reflective electrode RE3.

According to a stacking order of the light emitting layers GEML1a, BEML2a, and REML3a and the structure of the differential films DFL1 and DFL2 (or the structure of the differential patterns DFP1 and DFP2), the first resonance distance (e.g., the distance between the first reflective electrode RE1 and the cathode electrode CE) of the first light emitting element LD1 may be defined by (e.g., may include) four resonance layers r1r, r2r, r3r, and r4r with respect to red. When the third light emitting layer REML3a is disposed on one of the four resonance layers r1r, r2r, r3r, and r4r, the first light emitting element LD1 may emit red light having a luminance that is increased or maximized by a constructive interference. The first resonance layer rir may be spaced apart from the first reflective electrode RE1 by a length of ¼ of a wavelength 1 of red light. The second resonance layer r2r may be spaced apart from the first reflective electrode RE1 by a length of ¾ of a wavelength of red light. The third resonance layer r3r may be spaced apart from the first reflective electrode RE1 by a length of 5/4 of a wavelength of red light. The fourth resonance layer r4r may be spaced apart from the first reflective electrode RE1 by a length of 7/4 of a wavelength of red light. The fourth resonant layer r4r may be spaced apart from the cathode electrode CE by a length of ¼ of a wavelength of red light. Considering the thickness condition of the present embodiment, the third light emitting layer REML3a may be disposed in the fourth resonance layer r4r from among the four resonance layers r1r, r2r, r3r, and r4r.

The second resonance distance (e.g., the distance between the second reflective electrode RE2 and the cathode electrode CE) of the second light emitting element LD2 may be defined by (e.g., may include) six resonance layers b1r, b2r, b3r, b4r, b5r, and b6r with respect to blue. When the second light emitting layer BEML2a is disposed on one of the six resonance layers b1r, b2r, b3r, b4r, b5r, and b6r, the second light emitting element LD2 may emit blue light having a luminance that is increased or maximized by a constructive interference. The first resonance layer b1r may be spaced apart from the second reflective electrode RE2 by a length of ¼ of a wavelength of blue light. The second resonance layer b2r may be spaced apart from the second reflective electrode RE2 by a length of ¾ of a wavelength of blue light. The third resonance layer b3r may be spaced apart from the second reflective electrode RE2 by a length of 5/4 of a wavelength of blue light. The fourth resonance layer b4r may be spaced apart from the second reflective electrode RE2 by a length of 7/4 of a wavelength of blue light. The fifth resonance layer b5r may be spaced apart from the second reflective electrode RE2 by a length of 9/4 of a wavelength of blue light. The sixth resonance layer b6r may be spaced apart from the second reflective electrode RE2 by a length of 11/4 of a wavelength of blue light. The sixth resonant layer b6r may be spaced apart from the cathode electrode CE by a length of ¼ of a 1 wavelength of red light. Considering the thickness condition of the present embodiment, the second light emitting layer BEML2a may be disposed in the second resonance layer b2r from among the six resonance layers bir, b2r, b3r, b4r, b5r, and b6r.

The third resonance distance (e.g., the distance between the third reflective electrode RE3 and the cathode electrode CE) of the third light emitting element LD3 may be defined by (e.g., may include) five resonance layers g1r, g2r, g3r, g4r, and g5r with respect to green. When the first light emitting layer GEML1a is disposed on one of the five resonance layers g1r, g2r, g3r, g4r, and g5r, the third light emitting element LD3 may emit green light having a luminance that is increased or maximized by a constructive interference. The first resonance layer g1r may be spaced apart from the third reflective electrode RE3 by a length of ¼ of a wavelength of green light. The second resonance layer g2r may be spaced apart from the third reflective electrode RE3 by a length of ¾ of a wavelength of green light. The third resonance layer g3r may be spaced apart from the third reflective electrode RE3 by a length of 5/4 of a wavelength of green light. The fourth resonance layer g4r may be spaced apart from the third reflective electrode RE3 by a length of 7/4 of a wavelength of green light. The fifth resonance layer g5r may be spaced apart from the third reflective electrode RE3 by a length of 9/4 of a wavelength of green light. The fifth resonant layer g5r may be spaced apart from the cathode electrode CE by a length of ¼ of a wavelength of green light. Considering the thickness condition of the present embodiment, the first light emitting layer GEML1a may be disposed in the first resonance layer g1r from among the five resonance layers g1r, g2r, g3r, g4r, and g5r.

In more detail, the first light emitting layer GEML1a may be spaced apart from the third reflective electrode RE3 at an interval of 550 Å (Angstrom) or more and 750 Å or less. The second light emitting layer BEML2a may be spaced apart from the second reflective electrode RE2 at an interval of 1400 Å or more and 1600 Å or less. The third light emitting layer REML3a may be spaced apart from the first reflective electrode RE1 at an interval of 5600 Å or more and 5800 Å or less.

In addition, the second transparent electrode TE2 and the second reflective electrode RE2 of the second light emitting element LD2 may be spaced apart from each other by an interval of 150 Å or more and 350 Å or less. The third transparent electrode TE3 and the third reflective electrode TE3 of the third light emitting element LD3 may be spaced apart from each other by an interval of 400 Å or more and 600 Å or less.

In the present embodiment, the structure may include the differential films DFL1 and DFL2 described above with reference to FIG. 8A or the differential patterns DFP1 and DFP2 described above with reference to FIG. 8B, but the present disclosure is not limited thereto, and the first, second, and third resonance distances described above may be defined by the buffer patterns BFP1 and BFP2 and the planarization layer PLNL as described above with reference to FIG. 7. Accordingly, the present embodiment may be applied even to the structure described above with reference to FIG. 7.

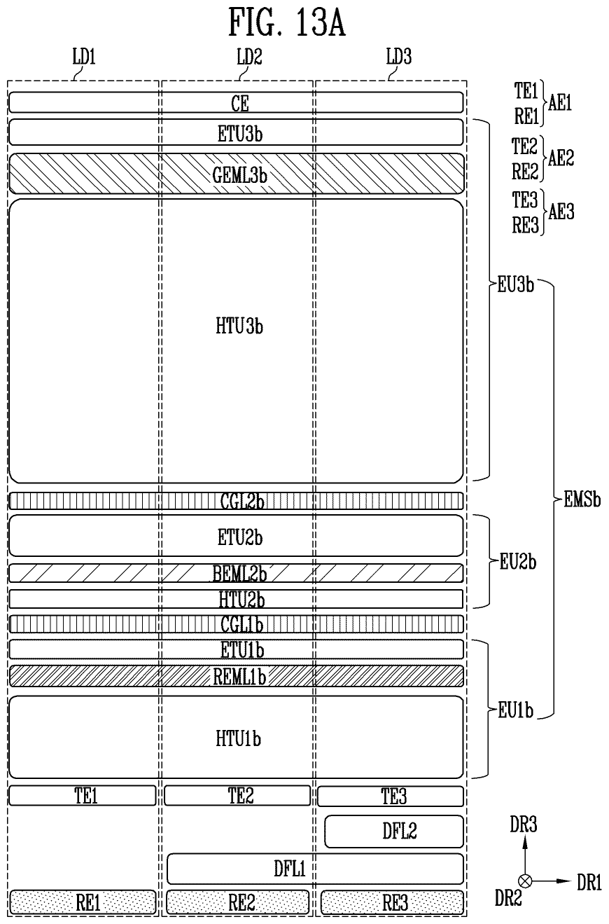

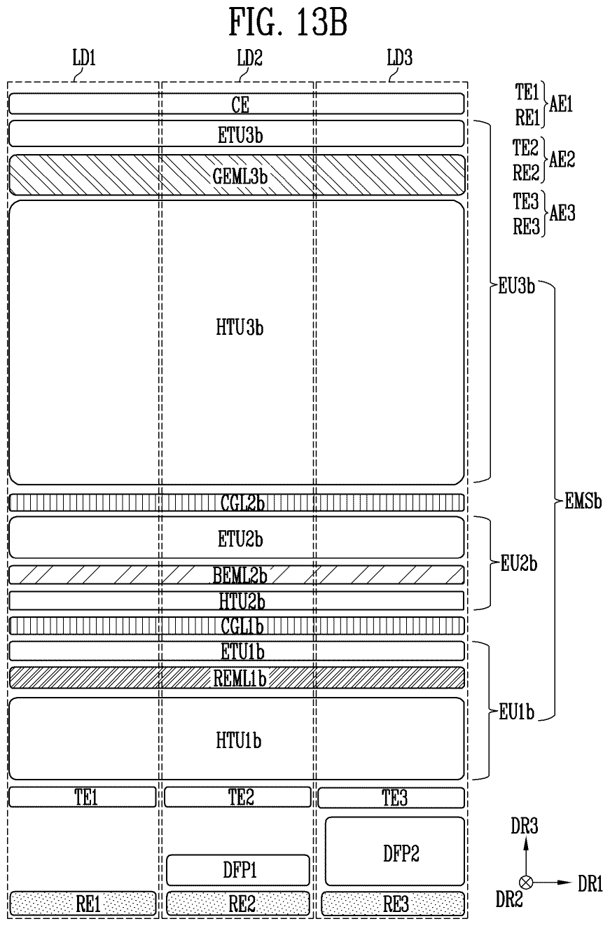

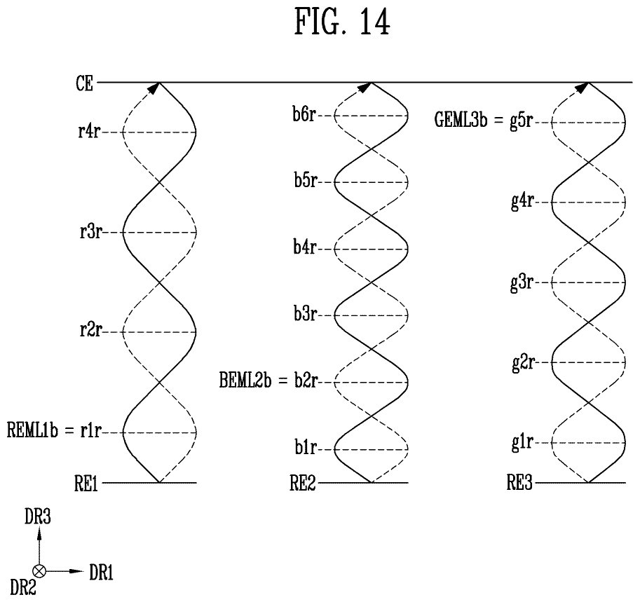

FIG. 13A illustrates first to third light emitting elements according to an embodiment of the present disclosure. FIG. 13B illustrates first to third light emitting elements according to an embodiment of the present disclosure. FIG. 14 illustrates first to third light emitting elements according to an embodiment of the present disclosure.

Referring to FIG. 13A and FIG. 13B, the first light emitting element LD1 disposed on the first reflective electrode RE1, the second light emitting element LD2 disposed on the second reflective electrode RE2, and the third light emitting element LD3 disposed on the third reflective electrode RE3 are illustrated.

The first light emitting element LD1, the second light emitting element LD2, and the third light emitting element LD3 may share the light emitting structure EMSb and the cathode electrode CE. The light emitting structure EMSb may include a first 1 light emitting portion EU1b, a second light emitting portion EU2b, and a third light emitting portion EU3b, which are sequentially stacked. The stacked structure of the light emitting structure EMSb may be the same or substantially the same as the stacked structure of the light emitting structure EMS' described above with reference to FIG. 10.

For example, the first light emitting portion EU1b may include a first hole transport portion HTU1b, a first light emitting layer REML1b, and a first electron transport portion ETU1b. The first light emitting layer REML1b may be disposed between the first hole transport portion HTU1b and the first electron transport portion ETU1b. The second light emitting portion EU2b may include a second hole transport portion HTU2b, a second light emitting layer BEML2b, and a second electron transport portion ETU2b. The second light emitting layer BEML2b may be disposed between the second hole transport portion HTU2b and the second electron transport portion ETU2b. The third light emitting portion EU3b may include a third hole transport portion HTU3b, a third light emitting layer GEML3b, and a third electron transport portion ETU3b. The third light emitting layer GEML3b may be disposed between the third hole transport portion HTU3b and the third electron transport portion ETU3b. The first charge generation layer CGL1b is disposed between the first light emitting portion EU1b and the second light emitting portion EU2b. The second charge generation layer CGL2b is disposed between the second light emitting portion EU2b and the third light emitting portion EU3b.

As described above, the separator SPR may disconnect the first light emitting portion EU1b, the first charge generation layer CGL1b, the second light emitting portion EU2b, and the second charge generation layer CGL2b, thereby preventing or substantially preventing a leakage current through a common layer between adjacent sub-pixels. In addition, the separator SPR may disconnect at least a portion of the third light emitting portion EU3b. However, the separator SPR may not disconnect the cathode electrode CE, which is a common electrode. When the 1 cathode electrode CE is disconnected by the separator SPR, the second power voltage VSS of the second power voltage node VSSN may not be transmitted to the cathode electrode CE of the light emitting elements LD1, LD2, and LD3, or an IR drop (a voltage drop) of the second power voltage VSS may occur.

In the present embodiment, the thickness of the third light emitting portion EU3b may be greater than the sum of the thicknesses of the first light emitting portion EU1b and the second light emitting portion EU2b. For example, the thickness of the third hole transport portion HTU3b included in the third light emitting portion EU3b may be greater than the sum of the thicknesses of the first light emitting portion EU1b and the second light emitting portion EU2b. The thickness may refer to a length in the third direction DR3.

For example, the thickness of the third light emitting portion EU3b may be 2.5 times or more than the sum of the thickness of the first light emitting portion EU1b and the thickness of the second light emitting portion EU2b. For example, the thickness of the third hole transport portion HTU3b included in the third light emitting portion EU3b may be 2.5 times or more than the sum of the thicknesses of the first light emitting portion EU1b and the second light emitting portion EU2b. For example, the thickness of the third light emitting portion EU3b may correspond to about 2.60 times the sum of the thickness of the first light emitting portion EU1b, the thickness of the first charge generation layer CGL1b, and the thickness of the second light emitting portion EU2b.

According to the present embodiment, while the first light emitting portion EU1b, the first charge generation layer CGL1b, the second light emitting portion EU2b, and the second charge generation layer CGL2b are disconnected by the separator SPR, the cathode electrode CE may not be disconnected by the separator SPR.

In this case, the thickness of the third light emitting portion EU3b or the thickness of the third hole transport portion HTU3b may be increased (e.g., may be continuously increased), but a power consumption for emitting light with the same or 1 substantially the same luminance may also be increased, and it may be difficult to match the resonance distance. Hereinafter, configurations for adjusting the resonance distance according to the above-described thickness conditions will be described in more detail.

In FIG. 13A, FIG. 13B, and FIG. 14, the first light emitting layer REML1b may emit red light. The second light emitting layer BEML2b may emit blue light. The third light emitting layer GEML3b may emit green light.

For example, the first color filter CF1 that allows red light to pass may be disposed on an upper portion of the first light emitting element LD1 (e.g., see FIG. 7, FIG. 8A, or FIG. 8B). In this case, the first light emitting element LD1 is an element for emitting red light, and it may be desired to set the resonance distance between the cathode electrode CE and the first reflective electrode RE1 so that the red light emitted from the first light emitting layer REML1b interferes constructively. The second color filter CF2 that allows blue light to pass may be disposed on an upper portion of the second light emitting element LD2. In this case, the second light emitting element LD2 is an element for emitting blue light, and it may be desired to set the resonance distance between the cathode electrode CE and the second reflective electrode RE2 so that the blue light emitted from the second light emitting layer BEML2b interferes constructively. The third color filter CF3 that allows green light to pass may be disposed on an upper portion of the third light emitting element LD3. In this case, the third light emitting element LD3 is an element for emitting green light, and it may be desired to set the resonance distance between the cathode electrode CE and the third reflective electrode RE3 so that the green light emitted from the third light emitting layer GEML3b interferes constructively.

Referring to FIG. 13A, as described above with reference to FIG. 8A, a differential film may not exist between the first transparent electrode TE1 and the first reflective electrode RE1 of the first light emitting element LD1. The first differential film DFL1 may exist between the second transparent electrode TE2 and the second reflective electrode RE2 of the second light emitting element LD2. The first differential film DFL1 and the second differential film DFL2 may exist between the third transparent electrode TE3 and the third reflective electrode RE3 of the third light emitting element LD3. Accordingly, the distance between the first transparent electrode TE1 and the first reflective electrode RE1 may be smaller than that between the second transparent electrode TE2 and the second reflective electrode RE2. In addition, the distance between the second transparent electrode TE2 and the second reflective electrode RE2 may be smaller than that between the third transparent electrode TE3 and the third reflective electrode RE3.

Referring to FIG. 13B, as described above with reference to FIG. 8B, a differential pattern may not exist between the first transparent electrode TE1 and the first reflective electrode RE1 of the first light emitting element LD1. The first differential pattern DFP1 may exist between the second transparent electrode TE2 and the second reflective electrode RE2 of the second light emitting element LD2. The second differential pattern DFP2 may exist between the third transparent electrode TE3 and the third reflective electrode RE3 of the third light emitting element LD3. The length of the second differential pattern DFP2 in the third direction DR3 may be greater than that of the first differential pattern DFP1 in the third direction DR3. Accordingly, the distance between the first transparent electrode TE1 and the first reflective electrode RE1 may be smaller than that between the second transparent electrode TE2 and the second reflective electrode RE2. In addition, the distance between the second transparent electrode TE2 and the second reflective electrode RE2 may be smaller than that between the third transparent electrode TE3 and the third reflective electrode RE3.

According to a stacking order of the light emitting layers REML1b, BEML2b, and GEML3b and the structure of the differential films DFL1 and DFL2 (or the structure of the differential patterns DFP1 and DFP2), the first resonance distance (e.g., the distance between the first reflective electrode RE1 and the cathode electrode CE) of the first light emitting element LD1 may be set to have four resonance layers r1r, r2r, r3r, and r4r with respect to red. When the first light emitting layer REML1b is disposed on one of the four resonance layers r1r, r2r, r3r, and r4r, the first light emitting element LD1 may emit red light having a luminance that is increased or maximized by a constructive interference. The first resonance layer rir may be spaced apart from the first reflective electrode RE1 by a length of ¼ of a wavelength of red light. The second resonance layer r2r may be spaced apart from the first reflective electrode RE1 by a length of ¾ of a wavelength of red light. The third resonance layer r3r may be spaced apart from the first reflective electrode RE1 by a length of 5/4 of a wavelength of red light. The fourth resonance layer r4r may be spaced apart from the first reflective electrode RE1 by a length of 7/4 of a wavelength of red light. The fourth resonant layer r4r may be spaced apart from the cathode electrode CE by a length of ¼ of a wavelength of red light. Considering the thickness condition of the present embodiment, the first light emitting layer REML1b may be disposed in the first resonance layer r1r from among the four resonance layers r1r, r2r, r3r, and r4r.

The second resonance distance (e.g., the distance between the second reflective electrode RE2 and the cathode electrode CE) of the second light emitting element LD2 may be set to have six resonance layers b1r, b2r, b3r, b4r, b5r, and b6r with respect to blue. When the second light emitting layer BEML2b is disposed on one of the six resonance layers b1r, b2r, b3r, b4r, b5r, and b6r, the second light emitting element LD2 may emit blue light having a luminance that is increased or maximized by a constructive interference. The first resonance layer bir may be spaced apart from the second reflective electrode RE2 by a length of ¼ of a wavelength of blue light. The second resonance layer b2r may be spaced apart from the second reflective electrode RE2 by a length of ¾ of a wavelength of blue light. The third resonance layer b3r may be spaced apart from the second reflective electrode RE2 by a length of 5/4 of a wavelength of blue light. The fourth resonance layer b4r may be spaced apart from the second reflective electrode RE2 by a length of 7/4 of a wavelength of blue light. The fifth resonance layer b5r may be spaced apart from the second reflective electrode RE2 by a length of 9/4 of a wavelength of blue light. The sixth resonance layer b6r may be spaced apart from the second reflective electrode RE2 by a length of 11/4 of a wavelength of blue light. The sixth resonant layer bor may be spaced apart from the cathode electrode CE by a length of ¼ of a wavelength of red light. Considering the thickness condition of the present embodiment, the second light emitting layer BEML2b may be disposed in the second resonance layer b2r from among the six resonance layers b1r, b2r, b3r, b4r, b5r, and b6r.

The third resonance distance (e.g., the distance between the third reflective electrode RE3 and the cathode electrode CE) of the third light emitting element LD3 may be set to have five resonance layers g1r, g2r, g3r, g4r, and g5r with respect to green. When the third light emitting layer GEML3b is disposed on one of the five resonance layers g1r, g2r, g3r, g4r, and g5r, the third light emitting element LD3 may emit green light having a luminance that is increased or maximized by a constructive interference. The first resonance layer g1r may be spaced apart from the third reflective electrode RE3 by a length of ¼ of a wavelength of green light. The second resonance layer g2r may be spaced apart from the third reflective electrode RE3 by a length of ¾ of a wavelength of green light. The third resonance layer g3r may be spaced apart from the third reflective electrode RE3 by a length of 5/4 of a wavelength of green light. The fourth resonance layer g4r may be spaced apart from the third reflective electrode RE3 by a length of 7/4 of a wavelength of green light. The fifth resonance layer g5r may be spaced apart from the third reflective electrode RE3 by a length of 9/4 of a wavelength of green light. The fifth resonant layer g5r may be spaced apart from the cathode electrode CE by a length of ¼ of a wavelength of green light. Considering the thickness condition of the present embodiment, the third light emitting layer GEML3b may be disposed in the fifth resonance layer g5r from among the five resonance layers g1r, g2r, g3r, g4r, and g5r.

In more detail, the first light emitting layer REML1b may be spaced apart from the first reflective electrode RE1 at an interval of 500 Å or more and 700 Å or less. The second light emitting layer BEML2b may be spaced apart from the second reflective electrode RE2 at an interval of 1400 Å or more and 1600 Å or less. The third light emitting layer GEML3b may be spaced apart from the third reflective electrode RE3 at an interval of 6400 Å or more and 6600 Å or less.

In addition, the second transparent electrode TE2 and the second reflective electrode RE2 of the second light emitting element LD2 may be spaced apart from each other by an interval of 200 Å or more and 400 Å or less. The third transparent electrode TE3 and the third reflective electrode RE3 of the third light emitting element LD3 may be spaced apart from each other by an interval of 600 Å or more and 800 Å or less.

In the present embodiment, the structure including the differential films DFL1 and DFL2 described above with reference to FIG. 8A or the differential patterns DFP1 and DFP2 described above with reference to FIG. 8B has been described, but the first, second, and third resonance distances described above may be set through the buffer patterns BFP1 and BFP2 and the planarization layer PLNL described above with reference to FIG. 7. Accordingly, the present embodiment may be applied even to the structure of FIG. 7.

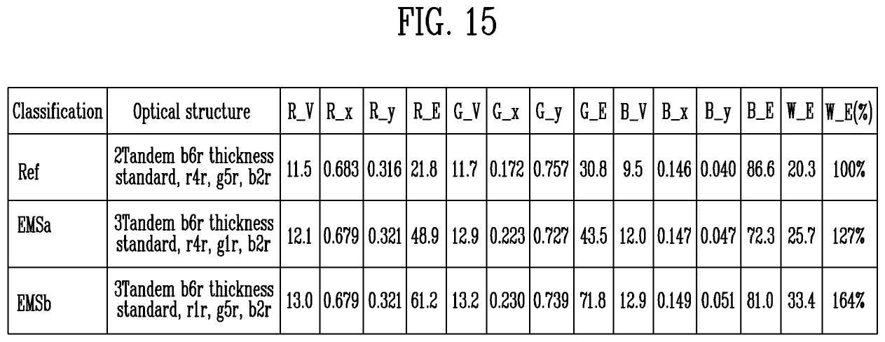

FIG. 15 is a table illustrating a light emitting efficiency of first to third light emitting elements according to an embodiment. FIG. 15 may illustrate a light emitting efficiency of the first to third light emitting elements described above with reference to FIG. 11A, FIG. 11B, FIG. 13A, and FIG. 13B.

Referring to FIG. 15, a table listing the red driving voltage R_V, the red color coordinates R_x and R_y, the red light emitting efficiency R_E, the green driving voltage G_V, the green color coordinates G_x and G_y, the green light emitting efficiency G_E, the blue driving voltage B_V, the blue color coordinates B_x and B_y, the blue light emitting efficiency B_E, and the white light emitting efficiency W_E for a comparative example Ref, the light emitting structure EMSa described above with FIG. 11A or FIG. 11B, and the light emitting structure EMSb described above with reference to FIG. 13A or FIG. 13B is shown.

The driving voltage may refer to a voltage at opposite ends (e.g., both ends) of the anode electrode and the cathode electrode. The color coordinates may refer to international commission on illumination (CIE) color coordinates. The light emitting efficiency may refer to a light emitting luminance compared to a power consumption.

The comparative example Ref has a structure of the light emitting structure EMS described above with reference to FIG. 9, but the second resonance distance of the second light emitting element LD for emitting blue light may be the same as the second resonance distance of the light emitting structures EMSa and EMSb. In the comparative example Ref, the red light emitting layer may be disposed in the fourth resonance layer r4r, the green light emitting layer may be disposed in the fifth resonance layer g5r, and the blue light emitting layer may be disposed in the second resonance layer b2r (e.g., see FIG. 12 or FIG. 14).

According to the experimental results, the light emitting structure EMSa described above with reference to FIG. 11A or FIG. 11B may have a white light emitting efficiency of 127% compared to that of the comparative example Ref. In addition, the light emitting structure EMSb described above with reference to FIG. 13A or FIG. 13B may have a white light emitting efficiency of 164% compared to that of the comparative example Ref. In addition, the separator SPR may disconnect the first light emitting portion EU1a or EU1b, the first charge generation layer CGL1a or CGL1b, the second light emitting portion EU2a or EU2b, and the second charge generation layer CGL2a or CGL2b, without disconnecting the cathode electrode CE.

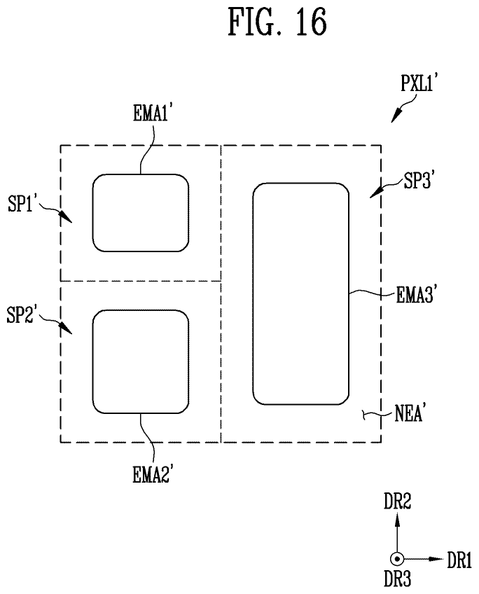

FIG. 16 illustrates a top plan view of one pixel of FIG. 5 according to an embodiment.

Referring to FIG. 16, a first pixel PXL1′ may include first to third sub-pixels SP1′ to SP3′.

The first sub-pixel SP1′ may include a first light emitting area EMA1′, and a non-light emitting area NEA′ around the first light emitting area EMA1′. The second sub-pixel SP2′ may include a second light emitting area EMA2′, and a non-light emitting area NEA′ around the second light emitting area EMA2′. The third sub-pixel SP3′ may include a third light emitting area EMA3′, and a non-light emitting area NEA′ around the third light emitting area EMA3′.

The first sub-pixel SP1′ and the second sub-pixel SP2′ may be disposed along the second direction DR2. The third sub-pixel SP3′ may be disposed in the first direction DR1 with respect to each of the first and second sub-pixels SP1′ and SP2′.

The second sub-pixel SP2′ may have a larger area than that of the first sub-pixel SP1′, and the third sub-pixel SP3′ may have a larger area than that of the second sub-pixel SP2′. Accordingly, the second light emitting area EMA2′ may have a larger area than that of the first light emitting area EMA1′, and the third light emitting area EMA3′ may have a larger area than that of the second light emitting area EMA2′. However, the present disclosure is not limited thereto. For example, the first and second sub-pixels SP1′ and SP2′ may have the same or substantially the same area (e.g., the same sized area) as each other, and the third sub-pixel SP3′ may have a larger area than that of each of the first and second sub-pixels SP1′ and SP2′. As such, the areas of the first to third sub-pixels SP1′ to SP3′ may be variously modified as needed or desired.

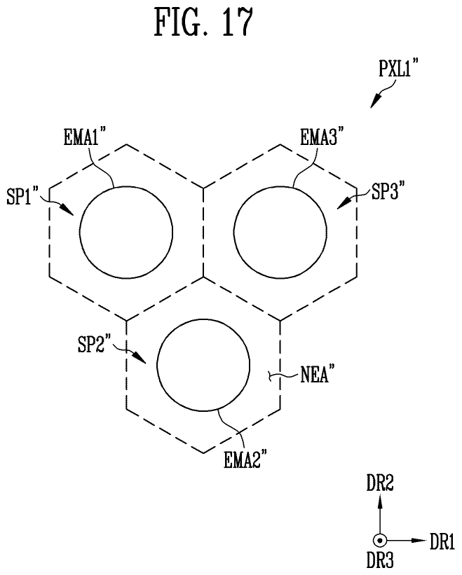

FIG. 17 illustrates a top plan view of one pixel of FIG. 5 according to an embodiment.

Referring to FIG. 17, the first sub-pixel SP1″ may include a first light emitting area EMA1″, and a non-light emitting area NEA″ around the first light emitting area EMA1″. The second sub-pixel SP2″ may include a second light emitting area EMA2″, and a non-light emitting area NEA″ around the second light emitting area EMA2″. The third sub-pixel SP3″ may include a third light emitting area EMA3″, and a non-light emitting area NEA″ around the third light emitting area EMA3″.

The first to third sub-pixels SP1″ to SP3″ may have polygonal shapes when viewed in the third direction DR3 (e.g., in a plan view). For example, the shapes of the first to third sub-pixels SP1″ to SP3″ may have hexagonal shapes as shown in FIG. 17.

The first to third light emitting areas EMA1″ to EMA3″ may have circular shapes when viewed in the third direction DR3 (e.g., in a plan view). However, the present disclosure is not limited thereto. For example, each of the first to third light emitting areas EMA1″ to EMA3″ may have a polygonal shape (e.g., a hexagonal shape).

The first and third sub-pixels SP1″ and SP3″ may be disposed along the first direction DR1. The second sub-pixel SP2″ may be disposed in a direction (e.g., a diagonal direction) inclined by an acute angle with respect to the second direction DR2 and with respect to the first sub-pixel SP1″.

The dispositions of the sub-pixels illustrated in FIGS. 6, 16, and 17 are provided as examples, and the present disclosure is not limited thereto. Each pixel may include two or more sub-pixels, the sub-pixels may be variously disposed as needed or desired, each of the sub-pixels may have various suitable shapes, and each of the light emitting areas may also have various suitable shapes.

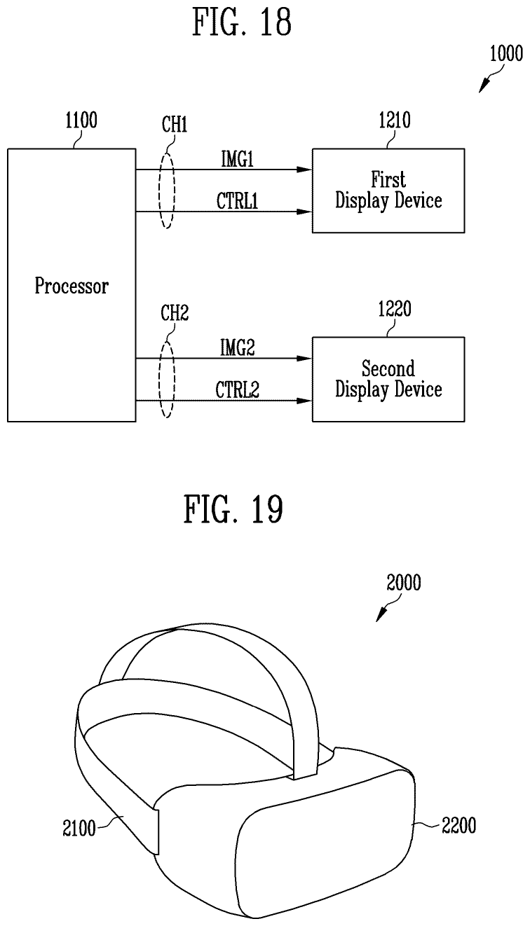

FIG. 18 illustrates a block diagram of a display system according to an embodiment.

Referring to FIG. 18, the display system 1000 may include a processor 1100 and one or more display devices 1210 and 1220.

The processor 1100 may perform various tasks and calculations. In embodiments, the processor 1100 may include an application processor, a graphics processor, a microprocessor, a central processing unit (CPU), and the like. The processor 1100 may be connected to and step other constituent elements of the display system 1000 through a bus system.

In FIG. 18, the display system 1000 is shown to include the first and second display devices 1210 and 1220. The processor 1100 may be connected to the first 1 display device 1210 through a first channel CH1 and to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this case, the second image data IMG2 and the second control signal CTRL2 may be provided as the input image data IMG and the control signal CTRL of FIG. 1, respectively.

The display system 1000 may include a computing system providing image display functions such as a portable computer, a mobile phone, a smart phone, a tablet personal computer (PC), a smart watch, a watch phone, a portable multimedia player (PMP), a navigation system, and a ultra mobile personal computer (UMPC). In addition, the display system 1000 may include at least one of a head-mounted display device (HMD), a virtual reality (VR) device, a mixed reality (MR) device, and an augmented reality (AR) device.

FIG. 19 illustrates a perspective view of an example of application of the display system of FIG. 18.

Referring to FIG. 19, the display system 1000 of FIG. 18 may be applied to a head-mounted display device 2000. The head-mounted display device 2000 may be a wearable electronic device that may be worn on the user's head.

The head-mounted display device 2000 may include a head-mounted band 2100 and a display device accommodation case 2200. The head-mounted band 2100 may be connected to the display device accommodation case 2200. The head-mounted band 2100 may include a horizontal band and/or a vertical band for fixing the head-mounted display device 2000 to the user's head. The horizontal band may be configured to surround the side portion of the user's head, and the vertical band may be configured to surround the upper portion of the user's head. However, the present disclosure is not limited thereto. For example, the head-mounted band 2100 may be implemented in the form of a spectacle frame, a helmet, or the like.

The display device accommodation case 2200 may accommodate the first and second display devices 1210 and 1220 of FIG. 12. The display device accommodation case 2200 may further accommodate the processor 1100 of FIG. 18.

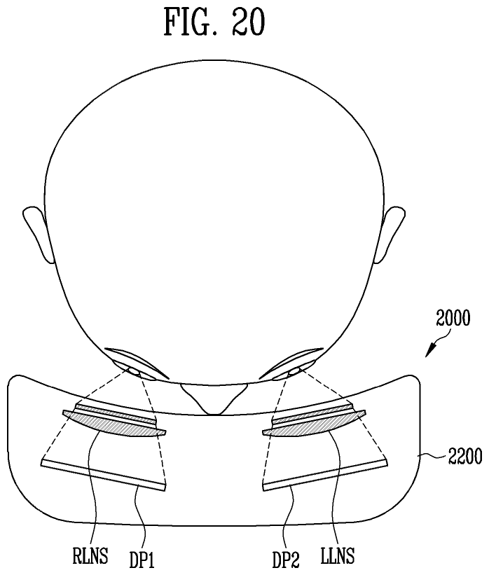

FIG. 20 illustrates a head-mounted display device of FIG. 19 worn on a user.

Referring to FIG. 20, a first display panel DP1 of the first display device 1210 and a second display panel DP2 of the second display device 1220 are disposed in the head mounted display device 2000. The head-mounted display device 2000 may further include one or more lenses LLNS and RLNS.

In the display device accommodation case 2200, the right eye lens RLNS may be disposed between the first display panel DP1 and the right eye of the user. In the display device accommodation case 2200, the left eye lens LLNS may be disposed between the second display panel DP2 and the left eye of the user.

An image outputted from the first display panel DP1 may be shown to the right eye of the user through the right eye lens RLNS. The right eye lens RLNS may refract light from the first display panel DP1 to be directed to the right eye of the user. The right eye lens RLNS may perform an optical function to adjust the viewing distance between the first display panel DP1 and the right eye of the user.

An image outputted from the second display panel DP2 may be shown to the left of the user through the left eye lens LLNS. The left eye lens LLNS may refract light from the second display panel DP2 to be directed to the left eye of the user. The left eye lens LLNS may perform an optical function to adjust the viewing distance between the second display panel DP2 and the left eye of the user.

In embodiments, each of the right eye lens RLNS and the left eye lens LLNS may include an optical lens having a cross-section of a pancake shape. In the embodiments, each of the right eye lens RLNS and the left eye lens LLNS may include a multi-channel lens including sub-areas with different optical characteristics. In this case, each display panel outputs images corresponding to the sub-areas of the multi-channel lens, and the output images may pass through the sub-areas and be viewed by the user.

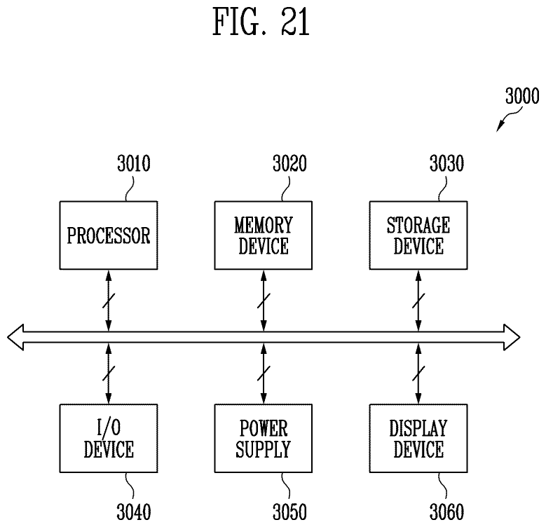

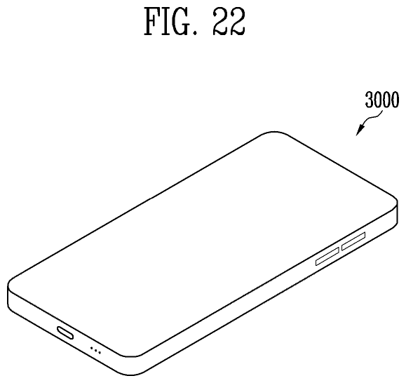

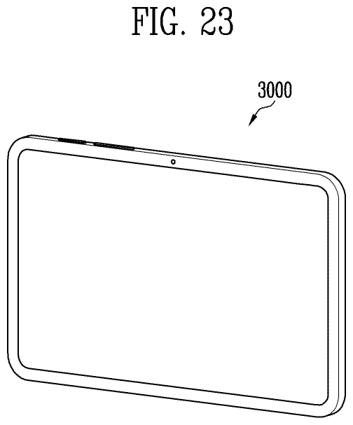

FIG. 21 is a schematic block diagram illustrating an electronic device 3000 including a display device in accordance with an embodiment. FIG. 22 is a schematic diagram illustrating an example where the electronic device 3000 of FIG. 21 is a smartphone. FIG. 23 is a schematic diagram illustrating an example where the electronic device 3000 of FIG. 21 is a tablet computer.

Referring to FIGS. 21 to 23, the electronic device 3000 may include a processor 1010, a memory device 1020, a storage device 1030, an input/output (I/O) device 1040, a power supply 1050, and a display device 1060. The display device 1060 may be the display device 100 of FIG. 1. The electronic device 3000 may further include various ports for communication with a video card, a sound card, a memory card, a USB device, or other systems. In an embodiment, as illustrated in FIG. 22, the electronic device 3000 may be a smartphone. In an embodiment, as illustrated in FIG. 23, the electronic device 3000 may be a tablet computer. However, the aforementioned examples are illustrative, and the electronic device 3000 is not necessarily limited to the aforementioned examples. For example, the electronic device 3000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may be a microprocessor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 3000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 3000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 3000. For example, the power supply 1050 may include a power management integrated circuit (PMIC). In an embodiment, the power supply 1050 may supply power to the display device 1060.

The display device 1060 may display images in response to control signals or data from the processor 1010. The display device 1060 may be connected to other components through the buses or other communication links.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a first light emitting element including a first reflective electrode;
a second light emitting element including a second reflective electrode; and
a third light emitting element including a third reflective electrode,
wherein the first light emitting element, the second light emitting element, and the third light emitting element share a light emitting structure and a cathode electrode,
wherein the light emitting structure comprises a first light emitting portion, a second light emitting portion, and a third light emitting portion sequentially stacked, and
wherein a thickness of the third light emitting portion is greater than a sum of a thickness of the first light emitting portion and a thickness of the second light emitting portion.

2. The display device of claim 1, wherein the thickness of the third light emitting portion is 2.5 times or more than the sum of the thickness of the first light emitting portion and the thickness of the second light emitting portion.

3. The display device of claim 1, wherein a thickness of a hole transport portion included in the third light emitting portion is greater than the sum of the thickness of the first light emitting portion and the thickness of the second light emitting portion.

4. The display device of claim 1, further comprising a separator between the first light emitting element, the second light emitting element, and the third light emitting element,
wherein the light emitting structure further comprises:
a first charge generation layer between the first light emitting portion and the second light emitting portion; and
a second charge generation layer between the second light emitting portion and the third light emitting portion,
wherein each of the first light emitting portion, the first charge generation layer, the second light emitting portion, and the second charge generation layer is disconnected by the separator, and
wherein the cathode electrode extends on an upper portion of the separator without being disconnected.

5. The display device of claim 1, wherein a distance between a first transparent electrode and a first reflective electrode of the first light emitting element is smaller than a distance between a second transparent electrode and a second reflective electrode of the second light emitting element.

6. The display device of claim 5, wherein the distance between the second transparent electrode and the second reflective electrode of the second light emitting element is smaller than a distance between a third transparent electrode and a third reflective electrode of the third light emitting element.

7. The display device of claim 6, wherein:
the first light emitting portion comprises a first light emitting layer configured to emit light of a first color;
the second light emitting portion comprises a second light emitting layer configured to emit light of a second color;
the third light emitting portion comprises a third light emitting layer configured to emit light of a third color; and
the first color, the second color, and the third color are different colors from each other.

8. The display device of claim 7, wherein the first color is green, the second color is blue, and the third color is red.

9. The display device of claim 8, wherein:
the first light emitting layer is located in a first resonance layer from among five resonance layers for the first color;
the second light emitting layer is located in a second resonance layer from among six resonance layers for the second color; and
the third light emitting layer is located in a fourth resonance layer from among four resonance layers for the third color.

10. The display device of claim 8, wherein:
the first light emitting layer is spaced from the third reflective electrode at an interval of 550 Å or more and 750 Å or less;
the second light emitting layer is spaced from the second reflective electrode at an interval of 1400 Å or more and 1600 Å or less; and
the third light emitting layer is spaced from the first reflective electrode at an interval of 5600 Å or more and 5800 Å or less.

11. The display device of claim 10, wherein:
the second transparent electrode and the second reflective electrode of the second light emitting element are spaced from each other at an interval of 150 Å or more and 350 Å or less; and
the third transparent electrode and the third reflective electrode of the third light emitting element are spaced apart from each other at an interval of 400 Å or more and 600 Å or less.

12. The display device of claim 7, wherein the first color is red, the second color is blue, and the third color is green.

13. The display device of claim 12, wherein:
the first light emitting layer is located in a first resonance layer from among four resonance layers for the first color;
the second light emitting layer is located in a second resonance layer from among six resonance layers for the second color; and
the third light emitting layer is located in a fifth resonance layer from among five resonance layers for the third color.

14. The display device of claim 12, wherein:
the first light emitting layer is spaced from the first reflective electrode at an interval of 500 Å or more and 700 Å or less;
the second light emitting layer is spaced from the second reflective electrode at an interval of 1400 Å or more and 1600 Å or less; and
the third light emitting layer is spaced from the third reflective electrode at an interval of 6400 Å or more and 6600 Å or less.

15. The display device of claim 14, wherein:
the second transparent electrode and the second reflective electrode of the second light emitting element are spaced from each other at an interval of 200 Å or more and 400 Å or less; and
the third transparent electrode and the third reflective electrode of the third light emitting element are spaced from each other at an interval of 600 Å or more and 800 Å or less.

16. The display device of claim 1, further comprising a substrate,
wherein a distance between the substrate and the first reflective electrode, a distance between the substrate and the second reflective electrode, and a distance between the substrate and the third reflective electrode are the same as each other.

17. The display device of claim 16, wherein a distance between the cathode electrode of the first light emitting element and the substrate, a distance between the cathode electrode of the second light emitting element and the substrate, and a distance between the cathode electrode of the third light emitting element and the substrate are different from each other.

18. The display device of claim 1, further comprising a substrate,
wherein a distance between the substrate and the first reflective electrode, a distance between the substrate and the second reflective electrode, and a distance between the substrate and the third reflective electrode are different from each other.

19. The display device of claim 18, wherein a distance between the cathode electrode of the first light emitting element and the substrate, a distance between the cathode electrode of the second light emitting element and the substrate, and a distance between the cathode electrode of the third light emitting element and the substrate are the same as each other.

20. A wearable device comprising:
a first display panel; and
a second display panel, each of the first display panel and the second display panel comprising:
a first light emitting element including a first reflective electrode;
a second light emitting element including a second reflective electrode; and
a third light emitting element including a third reflective electrode,
wherein the first light emitting element, the second light emitting element, and the third light emitting element share a light emitting structure and a cathode electrode,
wherein the light emitting structure comprises a first light emitting portion, a second light emitting portion, and a third light emitting portion sequentially stacked, and
wherein a thickness of the third light emitting portion is greater than a sum of a thickness of the first light emitting portion and a thickness of the second light emitting portion.

21. An electronic device comprising:
a processor to provide input image data; and
a display device to display an image based on the input image data, the display device comprising:
a first light emitting element including a first reflective electrode;
a second light emitting element including a second reflective electrode; and
a third light emitting element including a third reflective electrode,
wherein the first light emitting element, the second light emitting element, and the third light emitting element share a light emitting structure and a cathode electrode,
wherein the light emitting structure comprises a first light emitting portion, a second light emitting portion, and a third light emitting portion sequentially stacked, and
wherein a thickness of the third light emitting portion is greater than a sum of a thickness of the first light emitting portion and a thickness of the second light emitting portion.
